(19) United States
(12) Patent Application Publication
(10) Pub. No.: US 2026/0087971 A1
(43) Pub. Date: Mar. 26, 2026

(54) DISPLAY PANEL AND DISPLAY APPARATUS

(71) Applicant: Tianma Advanced Display Technology Institute (Xiamen) Co.,Ltd., Xiamen (CN)

(72) Inventors: Zhenyu JIA, Xiamen (CN); Jiali HUANG, Xiamen (CN); Kerui XI, Xiamen (CN); Tianyi WU, Xiamen (CN); Yingteng ZHAI, Xiamen (CN)

(21) Appl. No.: 18/986,192

(22) Filed: Dec. 18, 2024

(30) Foreign Application Priority Data
Sep. 25, 2024 (CN) 202411341403.2

(51) Int. Cl. G09G 3/32; G09G 3/3233

(52) U.S. Cl. CPC G09G 3/32; G09G 3/3233; G09G 2300/0426; G09G 2300/0819; G09G 2300/0852; G09G 2310/0286; G09G 2310/08; G09G 2330/04

(57) ABSTRACT

The present disclosure provides a display panel and a display apparatus. The display panel includes a plurality of shift register circuits in a display region and a plurality of first signal lines connected to the plurality of shift register circuits, where the plurality of first signal lines extends along a first direction and is arranged along a second direction, and the first direction intersects the second direction; and further includes a plurality of electrostatic protection circuits disposed in the display region, where along the first direction, an electrostatic protection circuit is on a side of an end portion of a first signal line facing toward an edge of the display panel, and the end portion of the first signal line is electrically connected to the electrostatic protection circuit.

### CROSS-REFERENCE TO RELATED APPLICATION

The present disclosure claims the priority of Chinese Patent Application No. 202411341403.2, filed on Sep. 25, 2024, the content of which is incorporated herein by reference in its entirety.

### TECHNICAL FIELD

The present disclosure generally relates to the field of display technology and, more particularly, relates to a display panel and a display apparatus.

### BACKGROUND

With continuous development of display technology, more display products, including mobile phones, tablets, laptops, smart wearable devices and the like, have been widely configured to be indispensable tools, which may bring great convenience to people's daily life. The effect of static electricity in environment may have an adverse effect on the display effect of display products. Therefore, there is a need to improve anti-static ability of display products.

### SUMMARY

One aspect of the present disclosure provides a display panel. The display panel includes a plurality of shift register circuits in a display region and a plurality of first signal lines connected to the plurality of shift register circuits, where the plurality of first signal lines extends along a first direction and is arranged along a second direction, and the first direction intersects the second direction; and further includes a plurality of electrostatic protection circuits disposed in the display region, where along the first direction, an electrostatic protection circuit is on a side of an end portion of a first signal line facing toward an edge of the display panel, and the end portion of the first signal line is electrically connected to the electrostatic protection circuit.

Another aspect of the present disclosure provides a display apparatus including a display panel. The display panel includes a plurality of shift register circuits in a display region and a plurality of first signal lines connected to the plurality of shift register circuits, where the plurality of first signal lines extends along a first direction and is arranged along a second direction, and the first direction intersects the second direction; and further includes a plurality of electrostatic protection circuits disposed in the display region, where along the first direction, an electrostatic protection circuit is on a side of an end portion of a first signal line facing toward an edge of the display panel, and the end portion of the first signal line is electrically connected to the electrostatic protection circuit.

Other aspects of the present disclosure may be understood by those skilled in the art in light of the description, the claims, and the drawings of the present disclosure.

### BRIEF DESCRIPTION OF THE DRAWINGS

The accompanying drawings, which are incorporated into a part of the specification, illustrate embodiments of the present disclosure and together with the description to explain the principles of the present disclosure.

In order to clearly explain embodiments of the present disclosure or the technical solutions in the existing technology, the drawings required for describing embodiments or the existing technology are briefly introduced hereinafter. Obviously, the drawings in the following description are merely embodiments of the present disclosure. Other drawings may also be obtained by those skilled in the art without any creative work according to provided drawings.

FIG. 1 illustrates a planar structural schematic of a display panel according to various embodiments of the present disclosure.

FIG. 2 illustrates a film layer schematic of a display panel according to various embodiments of the present disclosure.

FIG. 3 illustrates another planar structural schematic of a display panel according to various embodiments of the present disclosure.

FIG. 4 illustrates a connection schematic of a shift register circuit, a first signal line, a light-emitting element and a pixel driving circuit according to various embodiments of the present disclosure.

FIG. 5 illustrates another planar structural schematic of a display panel according to various embodiments of the present disclosure.

FIG. 6 illustrates another connection schematic of a shift register circuit, a first signal line, a light-emitting element and a pixel driving circuit according to various embodiments of the present disclosure.

FIG. 7 illustrates a schematic diagram of a first signal line not connected to an electrostatic protection circuit according to various embodiments of the present disclosure.

FIG. 8 illustrates another connection schematic of a shift register circuit, a first signal line, a light-emitting element and a pixel driving circuit according to various embodiments of the present disclosure.

FIG. 9 illustrates a circuit schematic of a first protection circuit and a second protection circuit according to various embodiments of the present disclosure.

FIG. 10 illustrates a schematic of a pixel driving circuit according to various embodiments of the present disclosure.

FIG. 11 illustrates a time sequence diagram corresponding to FIG. 10.

FIG. 12 illustrates a connection schematic of a first signal line and an electrostatic protection circuit corresponding to a pixel driving circuit according to various embodiments of the present disclosure.

FIG. 13 illustrates an arrangement schematic of first protection circuits and second protection circuits in a display panel according to various embodiments of the present disclosure.

FIG. 14 illustrates another arrangement schematic of first protection circuits and second protection circuits in a display panel according to various embodiments of the present disclosure.

FIG. 15 illustrates another arrangement schematic of first protection circuits and second protection circuits in a display panel according to various embodiments of the present disclosure.

FIG. 16 illustrates another arrangement schematic of first protection circuits and second protection circuits in a display panel according to various embodiments of the present disclosure.

FIG. 17 illustrates another arrangement schematic of first protection circuits and second protection circuits in a display panel according to various embodiments of the present disclosure.

FIG. 18 illustrates a circuit layout schematic of a display panel according to various embodiments of the present disclosure.

FIG. 19 illustrates a connection schematic of an electrostatic protection circuit, a first voltage line and a second voltage line according to various embodiments of the present disclosure.

FIG. 20 illustrates a structural schematic of an electrostatic protection circuit corresponding to FIG. 19.

FIG. 21 illustrates a structural schematic of a display apparatus according to various embodiments of the present disclosure.

### DETAILED DESCRIPTION

In order to clearly understand above-mentioned objectives, features and

advantages of the present disclosure, the solutions of the present disclosure are further described hereinafter. It should be noted that embodiments of the present disclosure and the features in embodiments may be combined with each other if there is no conflict.

Specific details are described in the following description to facilitate thorough understanding of the present disclosure, but the disclosure may also be implemented otherwise than as described herein. Obviously, embodiments in the description are only some of embodiments of the present disclosure, but not all embodiments.

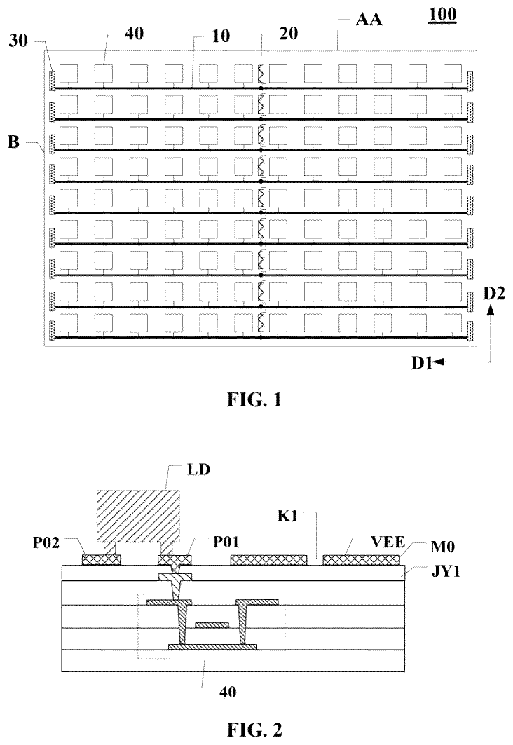

FIG. 1 illustrates a planar structural schematic of a display panel according to various embodiments of the present disclosure. Referring to FIG. 1, the present disclosure may provide a display panel 100, where the display panel 100 may include a plurality of shift register circuits 20 in the display region AA, and a plurality of first signal lines 10 connected to the plurality of shift register circuit 20; the first signal line 10 may extend along the first direction D1 and be arranged along the second direction D2; and the first direction D1 may intersect the second direction D2. The display panel 100 may further include a plurality of electrostatic protection circuits 30 disposed in the display region AA, where along the first direction D1, the electrostatic protection circuit 30 may be at the end portion of the first signal line 10 facing toward the edge B of the display panel, and the end portion of the first signal line 10 may be electrically connected to the electrostatic protection circuit 30.

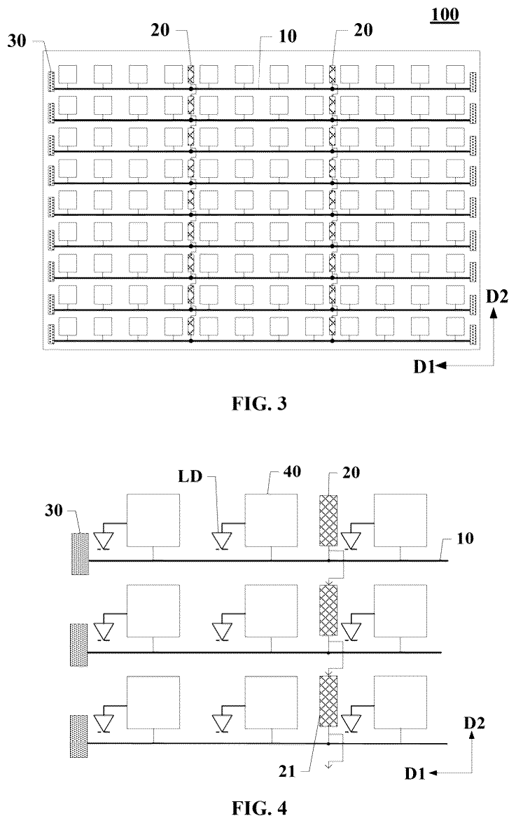

The display panel 100 of the rectangular structure is taken as an example for illustration in FIG. 1, which may not limit actual shape of the display panel. In some other embodiments of the present disclosure, the display panel may also be embodied in any other feasible shape such as a circle, a rounded rectangle, or the like. Optionally, the display panel provided in one embodiment may be a display panel using inorganic light-emitting diode display technology, such as a Micro LED display panel, a Mini LED display panel, or the like. Such type of display panels may have the advantages of high brightness, low power consumption, easy splicing and the like, and may be widely used in display products. The connection relationship of the light-emitting elements in the display panel may refer to FIG. 2. FIG. 2 illustrates a film layer schematic of the display panel according to various embodiments of the present disclosure. The light-emitting element LD may be electrically connected to the pixel driving circuit 40 in the display panel. It should be noted that FIG. 2 only illustrates a film layer structure of the display panel, which may not limit actual number and size of the film layers. In some other embodiments of the present disclosure, the display panel may also be embodied as an organic light-emitting display panel, and corresponding light-emitting element may be an organic light-emitting element (i.e., OLED), which may not be limited in the present disclosure. It should be noted that, in order to clearly illustrate relative positional relationship between the shift register circuits 20, the first signal lines 10 and the electrostatic protection circuits 30, other structures of the display panel such as the light-emitting elements LD and the like may be not shown in FIG. 1, and may only illustrate the pixel driving circuits 40 in rectangular structure, which may not limit the number and arrangement manner of the pixel driving circuits 40. In addition, the positions of the shift register circuits 20 in the display region in FIG. 1 may be only for illustration; and a group of shift register circuits 20 may be introduced in the display panel to be disposed in the middle region of the display region AA as an example for illustration, which may not limit the present disclosure. In some other embodiments of the present disclosure, the shift register circuits 20 may also be disposed at other positions in the display region. Referring to FIG. 3, FIG. 3 illustrates another planar structural schematic of the display panel according to various embodiments of the present disclosure. In one embodiment, two groups of shift register circuits 20 and two groups of electrostatic protection circuits 30 may be configured in the display panel to be respectively disposed in the left and right half-screen regions of the display panel as an example for illustration. The manner of providing control signals to the first signal lines 10 through two groups of shift register circuits 20 may be beneficial for improving the transmission efficiency and transmission reliability of the control signals.

FIG. 4 illustrates a connection schematic of the shift register circuit 20, the first signal line 10, the light-emitting element LD and the pixel driving circuit 40 according to various embodiments of the present disclosure. The pixel driving circuit 40 may be electrically connected to the light-emitting element LD to drive the light-emitting element LD to emit light. The first signal line 10 may be electrically connected to the pixel driving circuit 40. The control signal generated by the shift register circuit may be transmitted to the pixel driving circuit 40 through the first signal line 10 to control the operation of the pixel driving circuit 40. The structure of the pixel driving circuit 40 may refer to existing technology, which may not be limited in the present disclosure. In subsequent embodiments, the structure of the pixel driving circuit 40 may be described. Optionally, the shift register circuit 20 may include a plurality of cascaded shift register units 21. The shift register units 21 may be arranged along the second direction D2. The output terminal of the shift register unit may be connected to the first signal line 10, and the control signals may be provided to the pixel driving circuit 40 through the first signal line 10. The control signals may include, for example, a reset signal, a scan signal, a light-emitting control signal and/or the like.

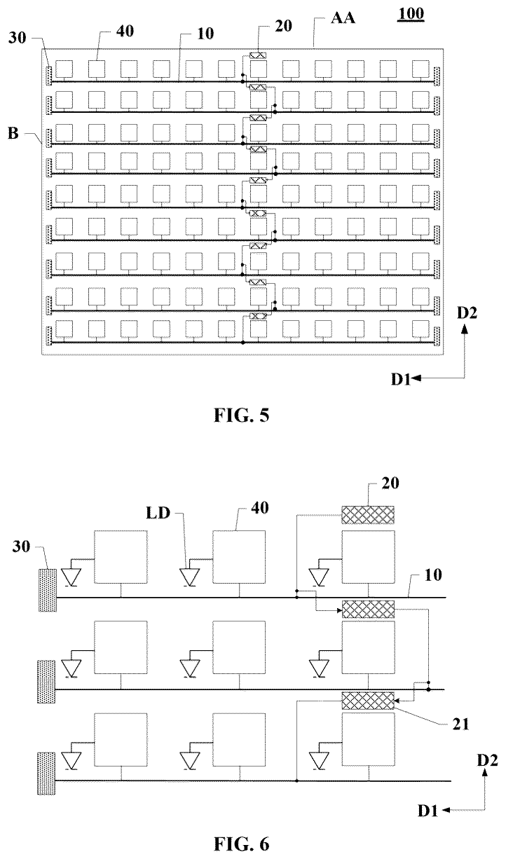

It should also be noted that the shift register circuits 20, the first signal lines 10 and the electrostatic protection circuits 30 in FIGS. 1, 3 and 4 may be only for illustration, which may not limit the number and positions of the shift register circuits 20, the first signal lines 10 and the electrostatic protection circuits 30 actually included in the display panel. The structure of the electrostatic protection circuit 30 may be described in subsequent embodiments. The shift register circuits 20 may be at the regions between pixel columns in FIGS. 1, 3 and 4, which may not be limited in the present disclosure. In some other embodiments of the present disclosure, the shift register circuits 20 may also be arranged between adjacent pixel rows. Referring to FIGS. 5-6, FIG. 5 illustrates another planar structural schematic of the display panel according to various embodiments of the present disclosure; and FIG. 6 illustrates another connection schematic of the shift register circuit, the first signal line, the light-emitting element and the pixel driving circuit according to various embodiments of the present disclosure. It should be noted that FIGS. 5-6 illustrate the solution that the shift register circuits 20 and the pixel driving circuits 40 may be at least partially overlapped with each other along the second direction, which may not be limited in the present disclosure. In some other embodiments of the present disclosure, along the second direction, the shift register circuits 20 and the pixel driving circuits 40 may be not overlapped with each other, or a part of the shift register circuits 20 and the pixel driving circuits 40 may be overlapped with each other.

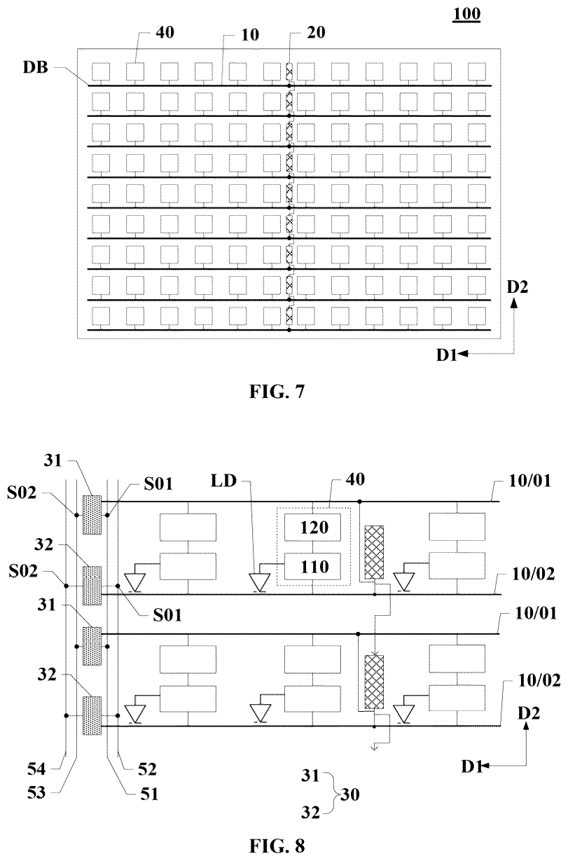

Referring to FIGS. 1-6, in the display panel provided by the present disclosure, the shift register circuit 20 may be configured in the display region AA, and the control signal may be provided to the first signal line 10 through the shift register circuit 20 in the display region AA; the electrostatic protection circuit 30 may be also configured in the display region AA; and the shift register circuit 20 and the electrostatic protection circuit 30 may not occupy the non-display region space of the display panel 100. In such way, a non-display region may not be configured in the display panel, or only a non-display region with a relatively small width may be configured in the display panel, which may be beneficial for realizing borderless or extremely narrow border design of the display panel. When the display panels with borderless structure are spliced to form a large-sized display panel, it may be beneficial for weakening the splicing seam and more beneficial for improving the display effect of the large-sized display panel. FIG. 7 illustrates a schematic diagram of the first signal line 10 not connected to the electrostatic protection circuit 30 according to various embodiments of the present disclosure. Referring to FIG. 7, when the shift register circuit 20 is configured in the display region, in order to simplify the connection between the shift register and the first signal line 10 and reduce wiring, the connection point between the first signal line 10 and the shift register circuit 20 may be in the non-end region of the first signal line 10. At this point, the end portions DB of the first signal line 10 located at two ends along the first direction D1 may float. If static electricity is in subsequent formation process or usage process of the display panel, static electricity may be able to act on the pixel driving circuit 40 through the end portion DB of the first signal line 10, which may affect the display effect of the display panel and even possibly damage relevant circuit structure. Therefore, referring to FIGS. 1, 3 and 4, in the present disclosure, the electrostatic protection circuit 30 may be configured in the display region, and the end portion of the first signal line 10 may be electrically connected to the electrostatic protection circuit 30. When the display panel 100 is subjected to static electricity, the static electricity may be discharged through the static electricity protection circuit 30 which may avoid affecting the display effect of the display panel and the circuit in the display panel, thereby being beneficial for improving overall anti-static ability of the display panel.

FIG. 8 illustrates another connection schematic of the shift register circuit 20, the first signal line 10, the light-emitting element LD and the pixel driving circuit 40 according to various embodiments of the present disclosure. In an optional embodiment of the present disclosure, the electrostatic protection circuits 30 may include the first protection circuit 31 and the second protection circuit 32; and the first protection circuit 31 and the second protection circuit 32 may be connected to different signals.

The display panel provided by the present disclosure may be as an inorganic light-emitting diode display panel as an example for description. The pixel driving circuit 40 connected to the light-emitting element LD may include a pulse width modulation circuit 120 and a pulse amplitude modulation circuit 110; and the pulse width modulation circuit 120 and the pulse amplitude modulation circuit 110 may be respectively connected to different first signal lines 10. The pulse width modulation circuit 120 may be connected to one first signal line 10, and the pulse amplitude modulation circuit 110 may be connected to one first signal line 10, which may be taken as an example for illustration and may not limit the number of first signal lines 10 connected to the pulse width modulation circuit 120 and the pulse amplitude modulation circuit 110 respectively. In one embodiment, the electrostatic protection circuits 30 may include the first protection circuit 31 and the second protection circuit 32. The first protection circuit 31 may be electrically connected to the end portion of the first signal line 10 corresponding to the pulse width modulation circuit 120; and the second protection circuit 32 may be electrically connected to the end portion of the first signal line 10 corresponding to the pulse amplitude modulation circuit 110. That is, the pulse width modulation circuit 120 and the pulse amplitude modulation circuit 110 may correspond to different electrostatic protection circuits 30 respectively. In one embodiment, the first protection circuit 31 and the second protection circuit 32 may be connected to different signals, which may be configured as the first protection circuit 31 and the second protection circuit 32 may be connected to different voltage lines. The signal transmitted on the voltage line connected to the first protection circuit 31 may be different from the signal transmitted on the voltage line connected to the second protection circuit 32. In such way, the electrostatic protection circuits 30 corresponding to different voltage domains may be introduced into the pulse amplitude modulation circuit 110 and the pulse width modulation circuit 120 in the pixel driving circuit 40, respectively, and electrostatic protection may be performed on the pulse width modulation circuit 120 and the pulse amplitude modulation circuit 110 respectively, which may be beneficial for improving overall anti-static ability of the display panel.

Referring to FIG. 8, in an optional embodiment of the present disclosure, the first protection circuit 31 and the second protection circuit 32 may respectively include the first signal terminal S01 and the second signal terminal S02; the first signal terminal S01 of the first protection circuit 31 may be configured to receive the first high voltage, and the second signal terminal S02 of the first protection circuit may be configured to receive a first low voltage; and the first signal terminal S01 of the second protection circuit 32 may be configured to receive the second high voltage, and the second signal terminal S02 of the second protection circuit 32 may be configured to receive the second low voltage, where the first high voltage may be not equal to the second high voltage, and/or the first low voltage may be not equal to the second low voltage.

For example, the first signal terminals S01 of the first protection circuit 31 and the second protection circuit 32 may be configured to receive the high voltage signals; and the second signal terminals S02 of the first protection circuit 31 and the second protection circuit 32 may be configured to receive the low voltage signals. Optionally, the first signal terminal S01 and the second signal terminal S02 may be respectively connected to different voltage lines. The voltage lines may be configured as electrostatic release lines. When high-voltage static electricity is generated on the first signal line 10, the first signal line 10 may release the high-voltage static electricity to the voltage line connected to the first signal terminal S01 through the electrostatic protection circuit 30 connected to the first signal line 10. When low-voltage static electricity is generated on the first signal line 10, the first signal line 10 may release the low-voltage static electricity to the voltage line connected to the second signal terminal S02 through the electrostatic protection circuit 30 connected to the first signal line 10. In one embodiment, the first signal terminal S01 and the second signal terminal S02 of the electrostatic protection circuit 30 may be connected to the high voltage signal and the low voltage signal, respectively, which may be beneficial for releasing high voltage electrostatic signals and low voltage electrostatic signals. In addition, the first protection circuit 31 and the second protection circuit 32 may be connected to different signals, which may include the following three scenarios. The first scenario is that the first high voltage connected to the first signal terminal S01 of the first protection circuit 31 may be different from the second high voltage connected to the first signal terminal S01 of the second protection circuit 32, and the first low voltage connected to the second signal terminal S02 of the first protection circuit 31 may be same as the second low voltage connected to the second signal terminal S02 of the second protection circuit 32. The second scenario is that the first high voltage connected to the first signal terminal S01 of the first protection circuit 31 may be same as the second high voltage connected to the first signal terminal S01 of the second protection circuit 32, and the first low voltage connected to the second signal terminal S02 of the first protection circuit 31 may be different from the second low voltage connected to the second signal terminal S02 of the second protection circuit 32. The third scenario is that the first high voltage connected to the first signal terminal S01 of the first protection circuit 31 may be different from the second high voltage connected to the first signal terminal S01 of the second protection circuit 32, and the first low voltage connected to the second signal terminal S02 of the first protection circuit 31 may be different from the second low voltage connected to the second signal terminal S02 of the second protection circuit 32. In such way, different voltage domain requirements of the pulse width modulation circuit 120 and the pulse amplitude modulation circuit 110 in the pixel driving circuit 40 may be matched, and overall electrostatic discharge effect of the display panel may be improved.

Referring to FIG. 8, in an optional embodiment of the present disclosure, the voltage value of the first high voltage corresponding to the first signal terminal S01 of the first protection circuit 31 is V11, the voltage value of the first low voltage corresponding to the second signal terminal S02 of the first protection circuit 31 is V01, the voltage value of the second high voltage corresponding to the first signal terminal S01 of the second protection circuit 32 is V12, and the voltage value of the second low voltage corresponding to the second signal terminal S02 of the second protection circuit 32 is V02, where V11−V01=V12−V02.

When V11−V01=V12−V02 is configured, it is equivalent to that the voltage difference between the first high voltage and the first low voltage corresponding to the first protection circuit 31 may be configured to be same as the voltage difference between the second high voltage and the second low voltage corresponding to the second protection circuit 32. For example, V11=8V, V01=−7V, the difference between V11 and V01 is 15V; V12=3V, V02=−12V, the difference between V12 and V02 is also 15V. The voltage difference corresponding to the first protection circuit 31 may be configured to be same as the voltage difference corresponding to the second protection circuit 32, which may be beneficial for simplifying the design difficulty of the voltage signals in the display panel. It should be noted that the values of V11, V01, V12 and V02 in one embodiment may be only exemplary, which may not limit actual voltage values. Above-mentioned voltage values may be flexibly configured according to actual circuit requirements.

In above-mentioned embodiment, the voltage difference between the high and low voltages corresponding to the first protection circuit 31 and the voltage difference between the high and low voltages corresponding to the second protection circuit 32 may be configured to be same. In an optional embodiment of the present disclosure, above-mentioned two voltage differences may also be designed to be different. For example, the voltage value of the first high voltage corresponding to the first signal terminal S01 of the first protection circuit 31 is V11, the voltage value of the first low voltage corresponding to the second signal terminal S02 of the first protection circuit 31 is V01, the voltage value of the second high voltage corresponding to the first signal terminal S01 of the second protection circuit 32 is V12, and the voltage value of the second low voltage corresponding to the second signal terminal S02 of the second protection circuit 32 is V02, where V11−V01≠V12−V02. When the difference between the high voltage and the low voltage corresponding to the first protection circuit 31 is configured to be different from the difference between the high voltage and the low voltage corresponding to the second protection circuit 32, the pixel driving circuit with corresponding voltage difference requirement may be matched, and the reliable release of static electricity may also be achieved, which may be beneficial for improving the anti-static performance of the display panel.

In an optional embodiment of the present disclosure, the voltage value of the first high voltage is V11, the voltage value of the first low voltage is V01, the voltage value of the second high voltage is V12, and the voltage value of the second low voltage is V02, where V11>V12>0, and V02<V01<0.

In embodiments of the present disclosure, the first high voltage and the first low voltage corresponding to the first protection circuit 31 are relative to OV voltage, and the second high voltage and the second low voltage corresponding to the second protection circuit 32 are also relative to OV voltage. For example, in the present disclosure, the first high voltage received by the first protection circuit 31 and the second high voltage received by the second protection circuit 32 may be both positive voltages, and the first low voltage received by the first protection circuit 31 and the second low voltage received by the second protection circuit 32 may be both negative voltages. That is, the voltage greater than OV may be configured as the high voltage, and the voltage less than OV may be configured as the low voltage. In such way, whether static electricity of positive voltage or static electricity of negative voltage acts on the display panel, the static electricity may be released through the static electricity protection circuit 30, thereby improving all-round anti-static performance of the display panel.

Referring to FIG. 8, in an optional embodiment of the present disclosure, the display region may include the light-emitting element LD and the pixel driving circuit 40 connected to the light-emitting element LD; the pixel driving circuit 40 may include the pulse width modulation circuit and the pulse amplitude modulation circuit; the first signal lines 10 may include the first-type signal line 01 and the second-type signal line 02; the first-type signal line 01 may be electrically connected to the pulse width modulation circuit, and the second-type signal line 02 may be electrically connected to the pulse amplitude modulation circuit; and the end portion of the first-type signal line 01 may be electrically connected to the first protection circuit 31, and the end portion of the second-type signal line 02 may be electrically connected to the second protection circuit 32.

In the pixel driving circuit 40, the pulse amplitude modulation circuit 110 may be configured to control the amplitude of the driving current, and the pulse width modulation circuit 120 may be configured to adjust the pulse width of the driving current applied to the light-emitting element LD. The pulse width modulation circuit 120 may be configured to adjust the pulse width of the voltage applied to the light-emitting element LD, that is, the pulse width modulation circuit 120 may adjust actual light-emitting period of the driving current applied to the light-emitting element LD. Meanwhile, the grayscale or brightness displayed by the light-emitting element LD may be adjusted by maintaining the driving current applied to the light-emitting element LD at a constant level, rather than adjusting the grayscale or brightness displayed by the light-emitting element LD through adjusting the magnitude of the driving current applied to the light-emitting element LD. Therefore, the pulse amplitude modulation circuit may provide the driving current to the light-emitting element LD, such that the light-emitting element LD may be driven with desirable light-emitting efficiency; and the light-emitting duty cycle of the light-emitting element LD (i.e., the light-emitting period of the light-emitting element LD) may be adjusted by the pulse width modulation circuit 120, thereby adjusting the grayscale or brightness displayed by the light-emitting element LD.

Referring to FIG. 8, in one embodiment, the first signal lines 10 may include the first-type signal line 01 connected to the pulse width modulation circuit 120 and the second-type signal line 02 connected to the pulse amplitude modulation circuit 110. The first-type signal line 01 may be configured to provide signals to the pulse width modulation circuit 120, such as scanning signals, frequency sweeping signals, light control signals, reset signals and/or the like. The second-type signal line 2 may be configured to provide signals to the pulse amplitude modulation circuit 110, such as scanning signals, light control signals, reset signals and/or the like. In the present disclosure, the end portion of the first-type signal line 01 may be electrically connected to the first protection circuit 31, and the end portion of the second-type signal line 02 may be electrically connected to the second protection circuit 32. When static electricity is generated on the first-type signal line 01, such part of the static electricity may be released through the first protection circuit 31; and when static electricity is generated on the second-type signal line 02, such part of the static electricity may be released through the second protection circuit 32. Therefore, the first protection circuit 31 and the second protection circuit 32 may be disposed to specifically perform electrostatic protection on the pulse width modulation circuit and the pulse amplitude modulation circuit in the pixel driving circuit 40, respectively, which may be beneficial for improving overall anti-static performance of the display panel.

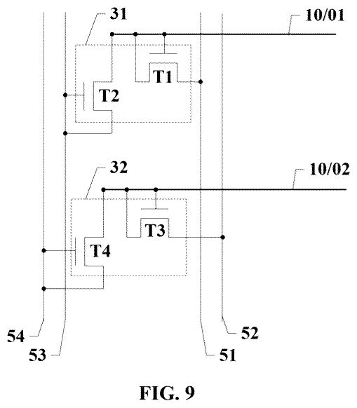

The structure of the electrostatic protection circuit is described hereinafter. FIG. 9 illustrates a circuit schematic of the first protection circuit 31 and the second protection circuit 32 according to various embodiments of the present disclosure. Referring to FIG. 9, in an optional embodiment of the present disclosure, the first protection circuit 31 may include the first transistor T1 and the second transistor T2. The gate electrode and the first electrode of the first transistor T1 may be electrically connected to the end portion of the first-type signal line 01, and the second electrode of the first transistor T1 may receive the first high voltage. The gate electrode and the first electrode of the second transistor T2 may receive the first low voltage, and the second electrode of the second transistor T2 may be electrically connected to the end portion of the first-type signal line 01. The second protection circuit 32 may include the third transistor T3 and the fourth transistor T4. The gate electrode and the first electrode of the third transistor T3 may receive the second high voltage, and the second electrode of the third transistor T3 may be electrically connected to the end portion of the second-type signal line 02. The gate electrode and the first electrode of the fourth transistor T4 may receive the second low voltage, and the second electrode of the fourth transistor T4 may be electrically connected to the end portion of the second-type signal line 02.

It should be noted that FIG. 9 only illustrates the structure and arrangement of one first protection circuit 31 and one second protection circuit 32. The structures of other first protection circuits 31 and other second protection circuits 32 may refer to FIG. 9. The first protection circuit 31 and the second protection circuit 32 may include two transistors respectively. In the first protection circuit 31, the gate electrode and the first electrode of the first transistor T1 may be connected to the first-type signal line 01, and the second electrode of the first transistor T1 may be connected to the voltage line 51 for receiving the first high voltage; and the gate electrode and the first electrode of the second transistor T2 may be connected to the voltage line 53 for receiving the first low voltage, and the second electrode of the second transistor T2 may be electrically connected to the first-type signal line 01. The first transistor T1 and the second transistor T2 may be transistors of same type. In one embodiment, the first transistor T1 and the second transistor T2 may be N-type transistors as an example for illustration. When high voltage static electricity is generated on the first-type signal line 01, the second transistor T2 may be cut off for disconnection, the first transistor T1 may be turned on for conduction, and the high voltage static electricity may be released through the voltage line 51. When low-voltage static electricity is generated on the first-type signal line 01, the second transistor T2 may be turned on for conduction, the first transistor T1 may be cut off for disconnection, and the low-voltage static electricity may be released through the voltage line 53. In such way, the first protection circuit 31 may be configured to realize the function of static electricity protection for the first-type signal line 01 and corresponding circuit.

In the second protection circuit 32, the gate electrode and the first electrode of the third transistor T3 may be electrically connected to the second-type signal line 02, and the second electrode of the third transistor T3 may be connected to the voltage line 52 for receiving the second high voltage; and the gate electrode and the first electrode of the fourth transistor T4 may be connected to the voltage line 54 for receiving the second low voltage, and the second electrode of the fourth transistor T4 may be electrically connected to the second-type signal line 02. The third transistor T3 and the fourth transistor T4 may be transistors of same type. In one embodiment, the third transistor T3 and the fourth transistor T4 may be N-type transistors as an example for illustration. It should be noted that the first protection circuit 31 and the second protection circuit 32 may correspond to four different voltage lines. When high voltage static electricity is generated on the second-type signal line 02, the fourth transistor T4 may be cut off for disconnection, the third transistor T3 may be turned on for conduction, and the high voltage static electricity may be released through the voltage line 52. When low-voltage static electricity is generated on the second-type signal line 02, the fourth transistor T4 may be turned on for conduction, the third transistor T3 may be cut off for disconnection, and the low-voltage static electricity may be released through the voltage line 54. In such way, the second protection circuit 32 may be configured to realize the function of static electricity protection for the second-type signal line 02 and corresponding circuit.

In one embodiment, the first high voltage may be configured to be different from the second high voltage, and/or the first low voltage may be configured to be different from the second low voltage. That is, the first protection circuit 31 corresponding to the first-type signal line 01 connected to the pulse width modulation circuit and the second protection circuit 32 corresponding to the second-type signal line 02 connected to the pulse amplitude modulation circuit may be connected to different voltage signals respectively, which may realize reliable conduction of static electricity and further be beneficial for different voltage domain requirements of the pulse width modulation circuit and the pulse amplitude modulation circuit.

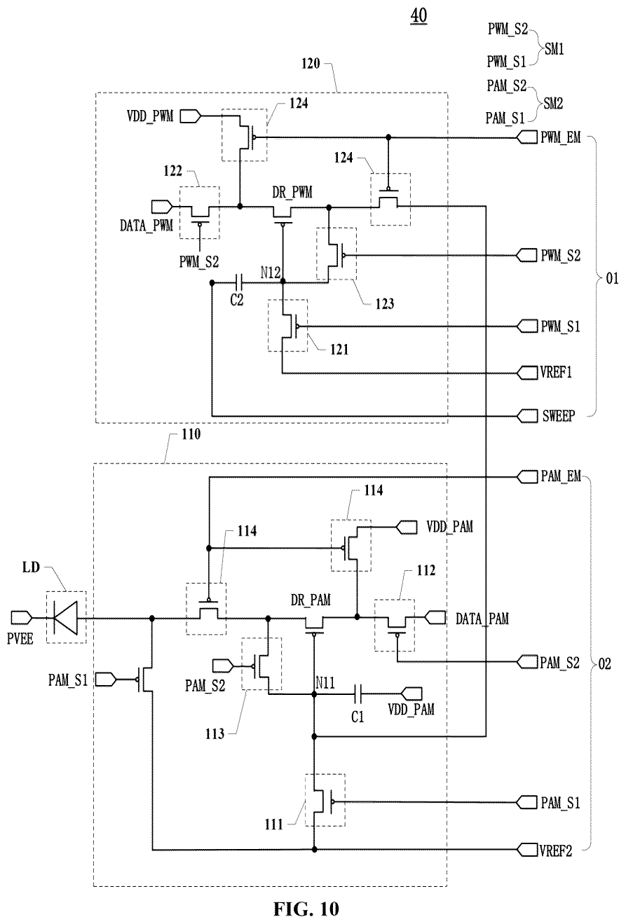

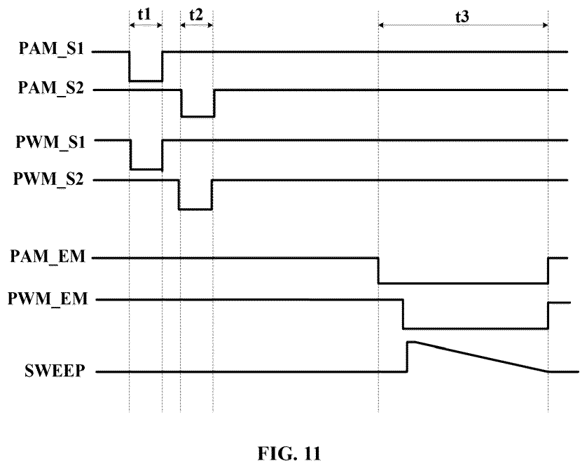

FIG. 10 illustrates a schematic of the pixel driving circuit 40 according to various embodiments of the present disclosure. Referring to FIGS. 8-10, in an optional embodiment of the present disclosure, the pixel driving circuit 40 may include a first scan line SM1, a first light-emitting control signal line PWM_EM, a first reset signal line VREF1 and a frequency sweeping signal line SWEEP which may be electrically connected to the pulse width modulation circuit 120, and include a second scan line SM2, a second light-emitting control signal line PAM_EM and a second reset signal line VREF2 which may be electrically connected to the pulse amplitude modulation circuit 110. The first-type signal lines 01 mentioned in embodiments of the present disclosure may include at least one of the first scan line SM1, the first light-emitting control signal line PWM_EM, the first reset signal line VREF1 and the frequency sweeping signal line SWEE; and the second-type signal lines 02 may include at least one of the second scan line SM2, the second light-emitting control signal line PAM_EM and the second reset signal line VREF2. In one embodiment, the first protection circuit 31 may be electrically connected to the first-type signal line 01 corresponding to the pulse width modulation circuit 120, and the second protection circuit 32 may be electrically connected to the second-type signal line 02 corresponding to the pulse amplitude modulation circuit 110. It should be noted that the power signal line VDD_PWM electrically connected to the pulse width modulation circuit 120 and the power signal line VDD_PAM electrically connected to the pulse amplitude modulation circuit may be mesh structures without floating signal terminals, such that the power signal lines VDD_PWM and VDD_PAM may not need to be electrically connected to the electrostatic protection circuits 30.

The signals transmitted by the first-type signal line 01 and the second-type signal line 02 is described in combination with the structure of the pixel driving circuit 40 hereinafter.

FIG. 11 illustrates a time sequence diagram corresponding to FIG. 10. Referring to FIGS. 10-11, in the present disclosure, the pixel driving circuit 40 may include the pulse amplitude modulation circuit 110 and the pulse width modulation circuit 120. The pulse amplitude modulation circuit 110 may be configured to control the amplitude of the driving current based on applied pulse amplitude modulation data, and the pulse width modulation circuit 120 may be configured to control the pulse width of the driving current.

It should be noted that the pixel driving circuit 40 shown in FIG. 10 may be only exemplary, and the present disclosure may not limit actual structure of the pixel circuit. In some other embodiments of the present disclosure, any other feasible pixel circuit structure may also be adopted. In the pixel driving circuit 40, the pulse width modulation circuit 120 may be electrically connected to the pulse amplitude modulation circuit 110, and the pulse amplitude modulation circuit 110 may be configured to be electrically connected to the light-emitting element LD.

Referring to FIGS. 10-11, optionally, the pulse amplitude modulation circuit 110 and the pulse width modulation circuit 120 may each include an initialization unit 111/121, a data writing unit 112/122, a threshold compensation unit 113/123, a light-emitting control unit 114/124, a storage capacitor C1/C2 and a driving transistor Dr_PAM/Dr_PWM, where the pulse amplitude modulation circuit 110 may include an initialization unit 111, a data writing unit 112, a threshold compensation unit 113, a light-emitting control unit 114, a storage capacitor C1 and a driving transistor Dr_PAM; and the pulse width modulation circuit 120 may include an initialization unit 121, a data writing unit 122, a threshold compensation unit 123, a light-emitting control unit 124, a storage capacitor C2 and a driving transistor Dr_PWM. The initialization unit 111/121 may be electrically connected between the initialization signal terminal VREF1/VREF2 and the first node N11/N12; and the initialization signal terminal VREF1/VREF2 may be connected to the reset signal line VREF1/VREF2 (the signal terminal and the signal provided by the signal terminal are represented by same character herein). The control terminal of the initialization unit 121 may be connected to the first scan line PWM_S1, and the control terminal of the initialization unit 111 may be connected to the second scan line PAM_S1. In an initialization stage t1, the first scan line PWM_S1 and the second scan line PAM_S1 may respectively control the initialization unit 121/111 to be turned on for conduction, and the initialization unit 111/121 may be configured to provide the initialization signal of the initialization signal terminal VREF1/VREF2 to the first node N11/N12. The initialization signal provided by the initialization signal terminal of the pulse amplitude modulation circuit 110 and the initialization signal provided by the initialization signal terminal of the pulse width modulation circuit 120 may have same value or different values.

The data writing unit 112/122 may be electrically connected between the data signal terminal DATA_PAM/DATA_PWM and the first electrode of the driving transistor Dr_PAM/Dr_PWM. The control terminal of the data writing unit 112 may be connected to the second scan line PAM_S2, and the control terminal of the data writing unit 111 may be connected to the first scan line PWM_S2. The first scan line PWM_S2 and the second scan line PAM_S2 may be configured to control the data writing unit 122 and the data writing unit 112 to be turned on respectively during a data writing stage. The gate electrode of the driving transistor Dr_PAM/Dr_PWM and the first plate of the storage capacitor C1/C2 may be electrically connected to the first node N11/N12; the data writing unit 112/122 may be configured to provide the data voltage signal of the data signal terminal DATA_PAM/DATA_PWM to the first node N11/N12 through the driving transistor Dr_PAM/Dr_PWM in a data writing stage t2. The threshold compensation unit 113/123 may be electrically connected between the second electrode of the driving transistor Dr_PAM/Dr_PWM and the first node N11/N12. The control terminal of the threshold compensation unit 113 may be connected to the second scan line PAM_S2, and the control terminal of the threshold compensation unit 123 may be connected to the first scan line PWM_S2. The threshold compensation unit 113/123 may be configured to compensate the threshold voltage of the driving transistor Dr_PAM/Dr_PWM to the first node N11/N12. It should be noted that in embodiments of the present disclosure, the scan lines corresponding to the pulse width modulation circuit 120 are collectively referred to as the first scan lines SM1, and the scan lines corresponding to the pulse amplitude modulation circuit 110 are collectively referred to as the second scan lines SM2. For example, there are multiple first scan lines SM1 connected to the pulse width modulation circuit 120, for example, the scan lines PWM_S1 and PWM_S2; the first scan lines with same drawing label may transmit same scanning signal; and the first scan lines with different drawing labels may transmit different scanning signals. Similarly, there are multiple second scan lines SM2 connected to the pulse amplitude modulation circuit 110, for example scan lines PAM_S1 and PAM_S2; the second scan lines with same drawing label may transmit same scan signal, and the second scan lines with different drawing labels may transmit different scan signals.

In the pulse width modulation circuit 120, the second electrode of the storage capacitor C2 may be electrically connected to the frequency sweeping signal terminal SWEEP, and the frequency sweeping signal terminal SWEEP may be electrically connected to the frequency sweeping signal line SWEEP to receive the frequency sweeping signal (the signal terminal and the signal provided by the signal terminal are represented by same character herein). The light-emitting control unit 124 may be electrically connected between the first power terminal VDD_PWM and the first node N11 in the pulse amplitude modulation circuit 110; and the control terminal of the light-emitting control unit 124 may be connected to the first light-emitting control signal line PWM_EM, which may be configured to transmit the light-emitting control signal to the light-emitting control unit 124. The light-emitting control unit 124 may be configured to control the driving transistor Dr_PWM to generate the driving pulse in a light-emitting stage t3; the first power terminal VDD_PWM may receive the first power voltage signal VDD_PWM (the signal terminal and the signal provided by the signal terminal are represented by same character herein); and the data signal terminal DATA_PWM may receive the pulse width modulated data voltage DATA_PWM (the signal terminal and the signal provided by the signal terminal are represented by same character herein).

In the pulse amplitude modulation circuit 110, the second electrode of the storage capacitor C1 may be electrically connected to the power signal terminal VDD_PAM, and the power signal terminal VDD_PAM may receive the second power voltage signal VDD_PAM (the signal terminal and the signal provided by the signal terminal are represented by same character herein). The light-emitting control unit 114 may be electrically connected between the power signal terminal VDD_PAM and the light-emitting element LD; and the control terminal of the light-emitting control unit 114 may be connected to the second light-emitting control signal line PAM_EM, which may be configured to transmit the light-emitting control signal to the light-emitting control unit 114. The light-emitting control unit 114 may be configured to control the driving transistor Dr_PAM to generate the driving current flowing into the light-emitting element LD in the light-emitting stage, which may drive the light-emitting element LD to emit light, and the data signal terminal DATA_PAM may receive the pulse amplitude modulated data voltage DATA_PAM (the signal terminal and the signal provided by the signal terminal are represented by same character herein).

In one embodiment, the output terminal of the pulse width modulation circuit 120 may be electrically connected to the first node N11 of the pulse amplitude modulation circuit 110, which may be configured to provide the control signal to the first node N11. Since the first node N11 is electrically connected to the gate electrode of the driving transistor Dr_PAM, it may be equivalent to providing the control signal to the gate electrode of the driving transistor Dr_PAM. In the pulse width modulation circuit 120, when the voltage difference between the gate electrode and the source electrode of the driving transistor Dr_PWM is greater than the threshold voltage of the driving transistor Dr_PWM, the driving transistor Dr_PWM may be in the cut-off state. At this point, the pulse width modulation circuit 120 may not provide the control signal to the first node N11 of the pulse amplitude modulation circuit 110, and the driving transistor Dr_PAM in the pulse amplitude modulation circuit 110 may provide the driving current to the light-emitting element LD according to the pulse amplitude modulation data voltage DATA_PAM. As the voltage of the frequency sweeping signal SWEEP changes, the gate potential of the driving transistor Dr_PWM may change synchronously. Until the voltage difference between the gate electrode and the source of the driving transistor Dr_PWM is less than or equal to the threshold voltage of the driving transistor Dr_PWM, the driving transistor Dr_PWM may be turned on for conduction, and the driving transistor Dr_PWM may transmit the first power voltage signal VDD_PWM of the first power terminal VDD_PWM as the cut-off voltage to the first node N11 of the pulse amplitude modulation circuit 110, such that the driving transistor Dr_PAM in the pulse amplitude modulation circuit 110 may be cut off for disconnection, thereby stopping the supply of the driving current to the light-emitting element LD.

It should be noted that, in embodiment of FIG. 10, the output terminal of the pulse width modulation circuit 120 may be directly connected to the gate electrode of the driving transistor Dr_PAM in the pulse amplitude modulation circuit 110. The pixel driving circuit 40 shown in FIG. 10 may be only exemplary, and the present disclosure may not limit actual structure of the pixel driving circuit 40. In some other embodiments of the present disclosure, any other feasible pixel driving circuit 40 structure may be adopted. For example, in some other embodiments of the present disclosure, the output terminal of the pulse width modulation circuit 120 may also be connected to the gate electrode of the driving transistor in the pulse amplitude modulation circuit 110 through a connection capacitor. For another example, the pulse amplitude modulation circuit 110 may also include a control transistor; the control transistor may be connected between the driving transistor Dr_PAM and the light-emitting element LD; and the output terminal of the pulse width modulation circuit 120 may be connected to the gate electrode of the control transistor.

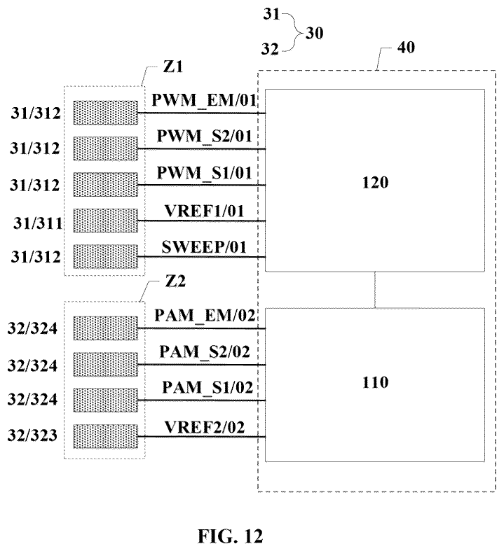

FIG. 12 illustrates a connection schematic of the first signal line 10 and the electrostatic protection circuit 30 corresponding to the pixel driving circuit 40 according to various embodiments of the present disclosure. The structures of the first protection circuit 31 and the second protection circuit 32 in FIG. 12 may refer to FIG. 9, and the structures of the pulse width modulation circuit and the pulse amplitude modulation circuit in FIG. 12 may refer to FIG. 10. Referring to FIGS. 9, 10 and 12, in an optional embodiment of the present disclosure, the first protection circuit 31 may include the first sub-circuit 311 and the second sub-circuit 312; the first sub-circuit 311 may be connected to the first reset signal line VREF1; the second sub-circuit 312 may be connected to at least one of the first scan line PWM_S1/PWM_S2, the first light-emitting control signal line PWM_EM, and the frequency sweeping signal line SWEEP; the channel width of the first transistor T1 in the first sub-circuit 311 is W11, and the channel width of the second transistor T2 is W12; and the channel width of the first transistor T1 in the second sub-circuit 312 is W21, and the channel width of the second transistor T2 is W22, where W11<W21, and/or, W12<W22.

For the first reset signal line VREF1, the reset signal provided by the first reset signal line VREF1 may be applicable to the pulse width modulation circuit 120 corresponding to each pixel driving circuit 40 in the display panel. That is, the reset signal provided by the first reset signal line VREF1 may be a global signal. If the width of the transistor in the electrostatic protection circuit 30 connected to the first reset signal line VREF1 is too large, corresponding leakage may also be relatively large, which may affect the reset reliability. Therefore, in one embodiment, the first protection circuit 31 connected to the first reset signal line VREF1 may be distinguished from the first protection circuit 31 connected to another first-type signal line 01. In the first-type signal lines 01 connected to the pulse width modulation circuit 120, the first protection circuit 31 connected to the first reset signal line VREF1 may be the first sub-circuit 311, and the first protection circuit 31 connected to another first-type signal line 01 (such as the first scan line PWM_S1/PWM_S2, the first light-emitting control signal line PWM_EM and/or the frequency sweeping signal line SWEEP) may be the second sub-circuit 312. The channel widths of the first transistor T1 and the second transistor T2 in the first sub-circuit 311 and the second sub-circuit 312 may be configured in the following three scenarios: the first scenario is that W11<W21, and W12-W22; the second scenario is that W12<W22, and W11=W21; and the third scenario is that W12<W21 and W12<W22. That is, the channel width of at least one transistor in the first subcircuit 311 may be less than the channel width of the transistor in the second subcircuit 312. Setting the size of the transistor in the first sub-circuit 311 to be relatively small may be beneficial for reducing the leakage of the first reset signal line VREF1 through the first sub-circuit 311, thereby improving the reset reliability of the pulse width modulation circuit 120 in the pixel driving circuit 40.

When the size of the transistor in the first sub-circuit 311 connected to the first reset signal line VREF1 is set to be relatively small, in an optional embodiment of the present disclosure, the channel widths of the first transistor T1 and the second transistor T2 in the plurality of second sub-circuits 312 may be same. In such way, the first transistor T1 and the second transistor T2 in the second sub-circuits 312 may be formed using same size standard, and there is no need to perform differentiated designs on the first transistor T1 and the second transistor T2 in different second sub-circuits 312, thereby being beneficial for simplifying the formation process of the display panel and improving the production efficiency of the display panel.

Referring to FIGS. 9, 10 and 12, in an optional embodiment of the present disclosure, the second protection circuit 32 may include the third sub-circuit 323 and the fourth sub-circuit 324; the third sub-circuit 323 may be connected to the second reset signal line VREF2; the fourth sub-circuit 324 may be connected to at least one of the second scan line PAM_S1/PAM_S2 and the second light-emitting control signal line PAM_EM; in the third sub-circuit 323, the channel width of the third transistor T3 is W13, and the channel width of the fourth transistor T4 is W14; and in the fourth sub-circuit 324, the channel width of the third transistor T3 is W23, and the channel width of the fourth transistor T4 is W24, where W13<W23, and/or, W14<W24.

For the second reset signal line VREF2, the reset signal provided by the second reset signal line VREF2 may be applicable to the pulse amplitude modulation circuit 110 corresponding to each pixel driving circuit 40 in the display panel. That is, the reset signal provided by the second reset signal line VREF2 may be a global signal. If the width of the transistor in the electrostatic protection circuit 30 connected to the second reset signal line VREF2 is too large, corresponding leakage may also be relatively large, which may affect the reset reliability. Therefore, in one embodiment, the second protection circuit 32 connected to the second reset signal line VREF2 may be distinguished from the second protection circuit 32 connected to another second-type signal line 02. In the second-type signal lines 02 connected to the pulse amplitude modulation circuit, the first protection circuit 31 connected to the second reset signal line VREF2 may be the third sub-circuit 323, and the second protection circuit 32 connected to another second-type signal line 02 (such as the second scan line PAM_S1/PAM_S2, and/or the second light-emitting control signal line PAM_EM) may be the fourth sub-circuit 324. The channel widths of the third transistor T3 and the fourth transistor T4 in the third sub-circuit 323 and the fourth sub-circuit 324 may be set in the following three scenarios: the first scenario is that W13<W23, and W14=W24; the second scenario is that W13<W23, and W14=W24; and the third scenario is that W13<W23 and W14<W24. That is, the channel width of at least one transistor in the third sub-circuit 323 may be less than the channel width of the transistor in the fourth sub-circuit 324. Setting the size of the transistor in the third sub-circuit 323 to be relatively small may be beneficial for reducing the leakage of the second reset signal line VREF2 through the third sub-circuit 323, thereby improving the reset reliability of the pulse amplitude modulation circuit in the pixel driving circuit 40.

When the size of the transistor in the third sub-circuit 323 connected to the second reset signal line VREF2 is set to be relatively small, in an optional embodiment of the present disclosure, the channel widths of the third transistor T3 and the fourth transistor T4 in the plurality of fourth sub-circuits 324 may be same. In such way, the third transistor T3 and the fourth transistor T4 in the fourth sub-circuit 324 may be formed using same size standard, and there is no need to perform differentiated designs on the third transistor T3 and the fourth transistor T4 in different fourth sub-circuits 324, thereby being beneficial for simplifying the formation process of the display panel and improving the production efficiency of the display panel.

Referring to FIGS. 9, 10 and 12, in an optional embodiment of the present disclosure, the first protection circuit 31 may include the first sub-circuit 311 and the second sub-circuit 312; the first sub-circuit 311 may be connected to the first reset signal line VREF1; the second sub-circuit 312 may be connected to at least one of the first scan line PWM_S1/PWM_S2, the first light-emitting control signal line PWM_EM, and the frequency sweeping signal line SWEEP; the second protection circuit 32 may include the third sub-circuit 323 and the fourth sub-circuit 324; the third sub-circuit 323 may be connected to the second reset signal line VREF2, and the fourth sub-circuit 324 may be connected to at least one of the second scan line PAM_S1/PAM_S2 and the second light-emitting control signal line PAM_EM; and the channel width of the transistor in the first sub-circuit 311 may be same as the channel width of the transistor in the third sub-circuit 323.

In one embodiment, the first reset signal line VREF1 may be connected to the pulse width modulation circuit 120, and the second reset signal line VREF2 may be connected to the pulse amplitude modulation circuit 110. To avoid electrostatic interference, the end portion of the first reset signal line VREF1 may be electrically connected to the first sub-circuit 311, the end portion of the second reset signal line VREF2 may be electrically connected to the third sub-circuit 323, the terminal of another first-type signal line 01 corresponding to the pulse width modulation circuit 120 may be electrically connected to the second sub-circuit 312, and the terminal of another second-type signal line 02 corresponding to the pulse amplitude modulation circuit 110 may be electrically connected to the fourth sub-circuit 324. In one embodiment, the sizes of transistors in the first sub-circuit 311 and the third sub-circuit 323 may be set to be relatively small. For example, W11<W21, and/or W12<W22; and W13<W23, and/or W14<W24, which may avoid excessive leakage on the first reset signal line VREF1 and the second reset signal line VREF2 to affect the reset effect. Meanwhile, in one embodiment, the channel width of the transistor in the first sub-circuit 311 may be set to be same as the channel width of the transistor in the third sub-circuit 323. For example, the channel width W11 of the first transistor T1 in the first sub-circuit 311 may be same as the channel width W13 of the third transistor T3 in the third sub-circuit 323, and the channel width W12 of the second transistor T2 in the first sub-circuit 311 may be same as the channel width W14 of the fourth transistor T4 in the third sub-circuit 323. In such way, same size standard and process may be configured to form the first sub-circuit 311 and the third sub-circuit 323, which may be beneficial for simplifying the formation process of the display panel and improving production efficiency. Optionally, the sizes of two transistors in the first sub-circuit 311 and the two transistors in the third sub-circuit 323 may be reduced, and W11=W12=W13=W14, which may be more beneficial for simplifying the formation process of the first sub-circuit 311 and the third sub-circuit 323.

Referring to FIGS. 9, 10 and 12, in an optional embodiment of the present disclosure, the channel widths of all transistors in the second sub-circuit 312 and the fourth sub-circuit 324 may be same. In such way, there is no need to distinguish the sizes of the transistors in the second sub-circuit 312 and the fourth sub-circuit 324. Same size standard may be configured to form the transistors in the second sub-circuit 312 and the fourth sub-circuit 324, which may be beneficial for simplifying the formation process of the second sub-circuit 312 and the fourth sub-circuit 324 and being beneficial for improving the production efficiency of the display panel.

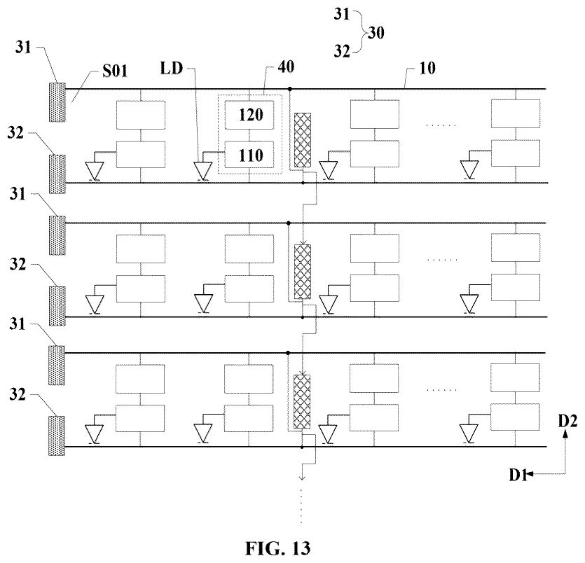

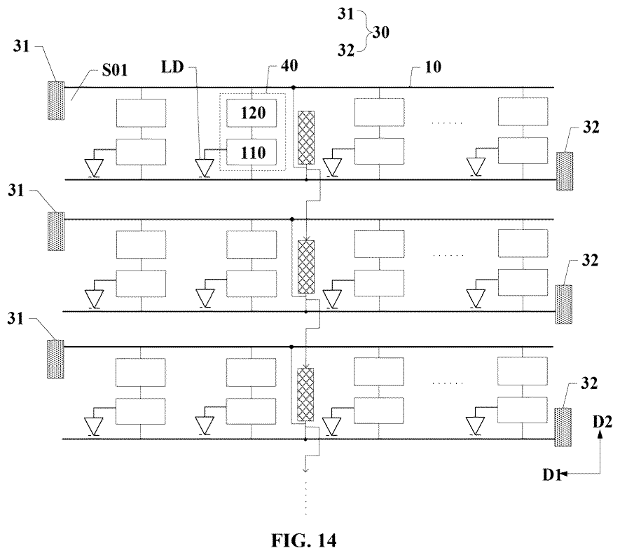

FIG. 13 illustrates an arrangement schematic of the first protection circuits 31 and the second protection circuits 32 in the display panel according to various embodiments of the present disclosure; and FIG. 14 illustrates another arrangement schematic of the first protection circuits 31 and the second protection circuits 32 in the display panel according to various embodiments of the present disclosure. In an optional embodiment of the present disclosure, referring to FIG. 13, along the first direction D1, the first protection circuit 31 and the second protection circuit 32 may be on one side of the first signal line 10; or referring to FIG. 14, along the first direction D1, the first protection circuit 31 may be on the first side of the first signal line 10, and the second protection circuit 32 may be on the second side of the first signal line 10, where the first side and the second side may be configured to be opposite to each other.

Embodiments of FIG. 13 and FIG. 14 illustrates two arrangements of the first protection circuits 31 and the second protection circuits 32 in the display panel. In one embodiment shown in FIG. 13, the first protection circuits 31 and the second protection circuits 32 may be on one side of the first signal lines 10 along the first direction D1. In one embodiment, the first protection circuits 31 and the second protection circuits 32 may be all on the left side of the first signal line 10, which may be taken as an example for illustration and may not be limited in the present disclosure. In some other embodiments of the present disclosure, the first protection circuits 31 and the second protection circuits 32 may also be all on the right side of the first signal lines 10. When static electricity is generated on the first signal line 10, the static electricity may be released through the first protection circuit 31 or the second protection circuit 32. In one embodiment shown in FIG. 14, the first protection circuit 31 and the second protection circuit 32 may be respectively on different sides of the first signal line 10 along the first direction D1. The first protection circuit 31 may be on the first side of the first signal line 10, and the second protection circuit 32 may be on the second side of the first signal line 10. When static electricity is generated on the first signal line 10, the static electricity may also be released through the first protection circuit 31 or the second protection circuit 32. The solutions shown in FIGS. 13-14 may be both beneficial for conducting out the static electricity and improving antistatic performance of the display panel.

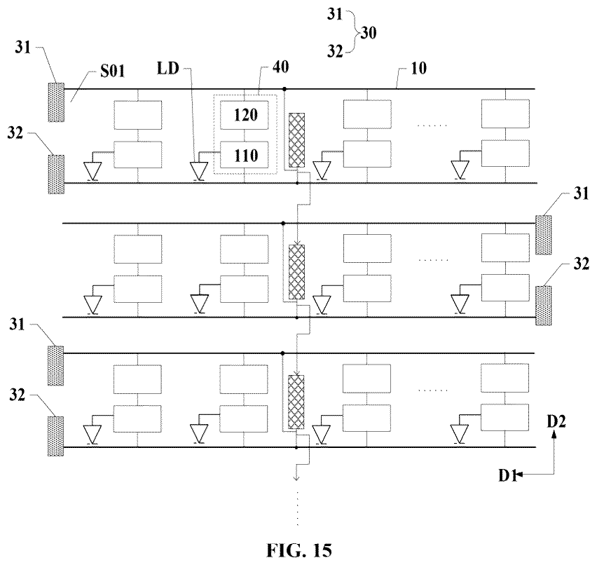

FIG. 15 illustrates another arrangement schematic of the first protection circuits 31 and the second protection circuits 32 in the display panel according to various embodiments of the present disclosure. Referring to FIG. 15, in an optional embodiment of the present disclosure, the electrostatic protection circuits 30 may be disposed on the first side and the second side of the first signal line 10 along the first direction D1, where the first side and the second side may be configured to be opposite to each other.

In one embodiment, it describes the solution that the first protection circuits 31 and the second protection circuits 32 may be disposed on the first side of the first signal line 10 along the first direction D1; and the first protection circuits 31 and the second protection circuits 32 may be also disposed on the second side of the first signal line 10 along the first direction D1. The first protection circuit 31 and the second protection circuit 32 corresponding to the pixel driving circuit 40 of the odd-numbered row may be on the first side of the first signal line 10, and the first protection circuit 31 and the second protection circuit 32 corresponding to the pixel driving circuit 40 of the even-numbered row may be on the second side of the first signal line 10. When static electricity is generated on the first signal line 10, the static electricity may be released through the first protection circuit 31 or the second protection circuit 32, which may be also beneficial for improving the static electricity release capability of the display panel.

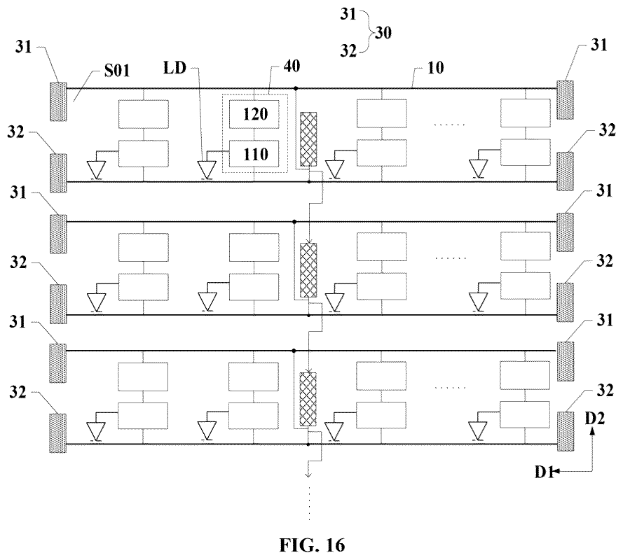

In above-mentioned embodiment, it describes the solution that one end portion of the first signal line 10 may be connected to the electrostatic protection circuit 30. In some other embodiments of the present disclosure, two end portions of the first signal line 10 may be electrically connected to the electrostatic protection circuit 30. For example, referring to FIG. 16, FIG. 16 illustrates another arrangement schematic of the first protection circuits 31 and the second protection circuits 32 in the display panel according to various embodiments of the present disclosure. In an optional embodiment of the present disclosure, two opposite end portions of the first signal line 10 along the first direction D1 may be electrically connected to the electrostatic protection circuit 30 respectively. In such way, two end portions of the first signal line 10 may not float. When static electricity is generated in the first signal line 10, the static electricity may be released through two static electricity protection circuits 30 connected to the first signal line 10, which may be beneficial for improving the static electricity release efficiency and reducing the time of the static electricity act on the display panel, thereby being more beneficial for improving overall anti-static ability of the display panel.

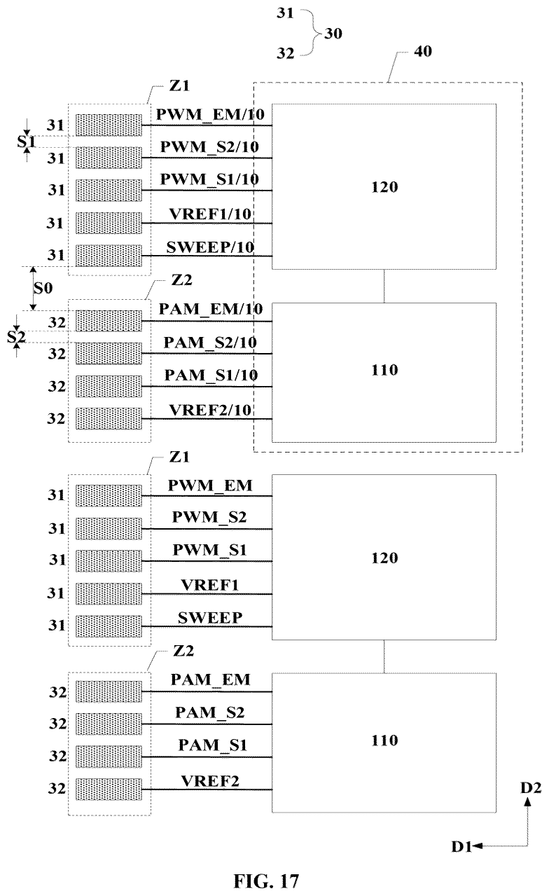

FIG. 17 illustrates another arrangement schematic of the first protection circuits 31 and the second protection circuits 32 in the display panel according to various embodiments of the present disclosure. Referring to FIG. 17, in an optional embodiment of the present disclosure, the electrostatic protection circuits 30 may include the first circuit group Z1 and the second circuit group Z2; the first circuit group Z1 may include a plurality of first protection circuits 31, and the second circuit group Z2 may include a plurality of second protection circuits 32; the plurality of first protection circuits 31 may be arranged along the second direction D2, and the plurality of second protection circuits 32 may be arranged along the second direction D2; on same side of the first signal line 10 along the first direction D1, the first circuit groups Z1 and the second circuit groups Z2 may be arranged alternately; and along the second direction D2, the distance between two adjacent first protection circuits 31 in the first circuit group Z1 is S1, the distance between two adjacent second protection circuits 32 in the second circuit group Z2 is S2, and the distance between the first circuit group Z1 and the second circuit group Z2 which are adjacent to each other is S0, where S0>S1, and/or S0>S2.

In one embodiment, along the second direction D2, the distance S0 between the first circuit group Z1 and the second circuit group Z2 which are adjacent to each other refers to the distance between the first protection circuit 31 and the second protection circuit 32 that are closest to each other in the first circuit group Z1 and the second circuit group Z2 which are adjacent. In one embodiment, the distance S0 between the first circuit group Z1 and the second circuit group Z2 may be configured to be relatively large, such that the distance S0 may be larger than at least one of the distance S1 between adjacent first circuits in the first circuit group Z1 and the distance S2 between adjacent second circuits in the second circuit group Z2, which may reasonably match the positions of the first signal lines drawn from the pulse width modulation circuit 120 and the pulse amplitude modulation circuit 110, and simplify the connection between the electrostatic protection circuits and the first signal lines.

Referring to FIG. 17, in an optional embodiment of the present disclosure, along the first direction D1, the distance S1 between adjacent first protection circuits 31 in the first circuit group Z1 and the distance S2 between adjacent second protection circuits 32 in the second circuit group Z2 may satisfy the relationship: S1=S2. In such way, it may be equivalent to arranging the first protection circuits 31 in the first circuit group Z1 and the second protection circuits 32 in the second circuit group Z2 at equal intervals, which may be beneficial for simplifying the arrangement complexity of the first protection circuits 31 and the second protection circuits 32 and also simplifying the layout structure of the electrostatic protection circuits 30 in the display panel.

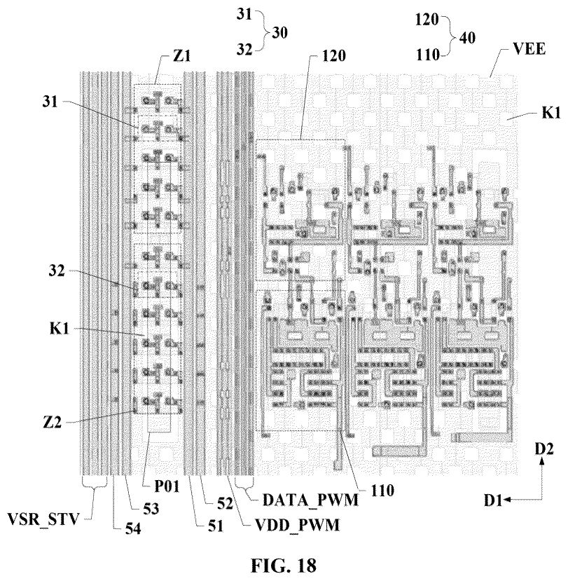

FIG. 18 illustrates a circuit layout schematic of the display panel according to various embodiments of the present disclosure. It should be noted that FIG. 18 may only illustrate a part of the film layers in the display panel and may not show entire film layer structure in the display panel. The relative position relationship of the first circuit groups Z1, the second circuit groups Z2, the pixel driving circuits 40, the anode soldering pads P01 of the light-emitting elements LD and other structures may be illustrated, and the arrangement of the voltage lines 51/52/53/54 connected to the electrostatic protection circuits 30, the trigger signal lines VSR_STV connected to the shift register circuits, and the data lines DATA_PWM and the power lines VDD_PWM corresponding to the pulse width modulation circuits 120 may be illustrated, which may not limit actual arrangement of above-mentioned signal lines. Optionally, above-mentioned signal lines may be arranged in same layer. Referring to FIGS. 2 and 18, in an optional embodiment of the present disclosure, the electrostatic protection circuit 30 may be overlapped with the light-emitting element LD along the direction perpendicular to the plane where the light-emitting surface of the display panel is located. It should be noted that FIG. 18 may only show the anode soldering pad P01 for binding the light-emitting element LD, and may not show the light-emitting element LD. The relative position relationship between the light-emitting element LD and the anode soldering pad P01 may be referred to FIG. 2. The electrode of the light-emitting element LD may be bound to the anode soldering pad P01 and the cathode soldering pad P02. When the anode soldering pad P01 is overlapped with the electrostatic protection circuit 30, the light-emitting element LD may be also overlapped with the electrostatic protection circuit 30. In actual production process, the electrode of the light-emitting element LD may be bonded to the anode soldering pad P01 and the cathode soldering pad P02 by a bonding manner. After the light-emitting element LD is bound to the anode soldering pad P01 and the cathode soldering pad P02, the light-emitting element LD may be overlapped with the electrostatic protection circuit 30 along the direction perpendicular to the plane where the display panel is located. A part of the electrostatic protection circuit 30 may be below the light-emitting chip of the light-emitting element LD. In such way, the effective space in the display panel may be fully utilized, and the space utilization rate of the display panel may be improved.

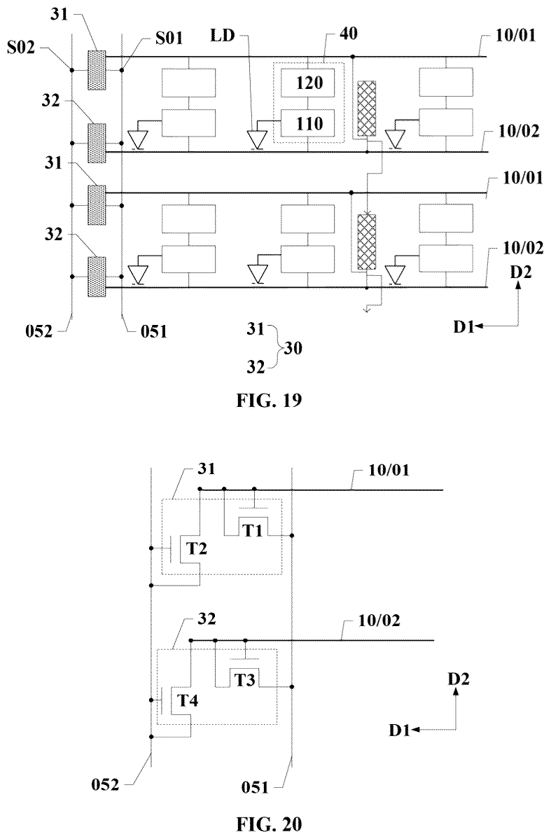

FIG. 19 illustrates a connection schematic of the electrostatic protection circuit 30, the first voltage line and the second voltage line according to various embodiments of the present disclosure; and FIG. 20 illustrates a structural schematic of the electrostatic protection circuit corresponding to FIG. 19. Referring to FIGS. 19-20, in an optional embodiment of the present disclosure, the display panel may further include the pixel driving circuit 40, and the pixel driving circuit 40 may be on one side of the electrostatic protection circuit 30 away from the edge of the display panel along the first direction D1; the display region may include the first voltage line and the second voltage line; the first signal terminal S01 of the electrostatic protection circuit 30 may be electrically connected to the first voltage line 051, and the second signal terminal S02 of the electrostatic protection circuit 30 may be electrically connected to the second voltage line 052; and along the first direction D1, the first voltage line 051 and the second voltage line 052 may be on two sides of the electrostatic protection circuit 30, and the first voltage line 051 may be between the electrostatic protection circuit 30 and the pixel driving circuit 40.

Referring to FIGS. 19-20, in the present disclosure, the electrostatic protection circuits 30 may include the first protection circuit 31 and the second protection circuit 32. The first protection circuit 31 may be configured to electrically connect to the end portion of the first-type signal line 01 connected to the pulse width modulation circuit 120, and the second protection circuit 32 may be configured to electrically connect to the end portion of the second-type signal line 02 connected to the pulse amplitude modulation circuit 110. The first protection circuit 31 may include the first transistor T1 and the second transistor T2; and the second protection circuit 32 may include the third transistor T3 and the fourth transistor T4. In the first protection circuit 31, optionally, the first transistor T1 and the second transistor T2 may be arranged along the first direction D1; the gate electrode and the first electrode of the first transistor T1, and the second electrode of the second transistor T2 may be electrically connected to the end portion of the first-type signal line 01; the second electrode of the first transistor T1 may be connected to the first voltage line 051 to receive the high voltage; and the gate electrode and the first electrode of the second transistor T2 may be connected to the second voltage line 052 to receive the low voltage. In the second protection circuit 32, optionally, the third transistor T3 and the fourth transistor T4 may be arranged along the first direction D1; the gate electrode and the first electrode of the third transistor T3, and the second electrode of the fourth transistor T4 may be connected to the end portion of the second-type signal line 02; the second electrode of the third transistor T3 may be connected to the first voltage line 051 to receive the high voltage; and the gate electrode and the first electrode of the fourth transistor T4 may be connected to the second voltage line 052 to receive the low voltage. It may be seen that in the first protection circuit 31 and the second protection circuit 32, the second electrode of the first transistor T1 and the second electrode of the third transistor T3 may be connected to the first voltage line; setting the first voltage line on same side of the first transistor T1 and the third transistor T3 along the first direction D1 may be beneficial for simplifying the connection of the first voltage line 051; the gate electrode and the first electrode of the second transistor T2 and the gate electrode and the first electrode of the fourth transistor T4 may be connected to the second voltage line 052; and setting the second voltage line 052 on same side of the second transistor T2 and the fourth transistor T4 along the first direction D1 may be beneficial for simplifying the connection of the second voltage line 052. Therefore, when the second transistor T2 in the first protection circuit 31 is disposed between the first transistor T1 and the edge of the display panel, when the fourth transistor T4 in the second protection circuit 32 is disposed between the third transistor T3 and the edge of the display panel and when the first voltage line 051 and the second voltage line 052 are respectively arranged on two sides of the electrostatic protection circuit 30 along the first direction D1, the first voltage line 051 may be configured to be close to the first transistor T1 and the third transistor T3, and the second voltage line 052 may be configured to be close to the second transistor T2 and the fourth transistor T4. That is, setting the first voltage line 051 between the electrostatic protection circuit 30 and the pixel driving circuit 40, and setting the second voltage line 052 between the electrostatic protection circuit 30 and the edge of the display panel may be beneficial for simplifying the connection between the first transistor T1 and the third transistor T3 and the first voltage line 051 and beneficial for simplifying the connection between the second transistor T2 and the fourth transistor T4 and the second voltage line 052, thereby being beneficial for simplifying overall wiring complexity of the display panel.

It should be noted that when the positions of the first transistor T1 and the second transistor T2 in the first protection circuit 31 are switched, and when the positions of the third transistor T3 and the fourth transistor T4 in the second protection circuit 32 are switched, the positions of the first voltage line 051 and the second voltage line 052 may be also switched accordingly. At this point, the second voltage line 052 may be between the electrostatic protection circuit 30 and the pixel driving circuit 40, which may also simplify the connection between the first voltage line 051 and each of the first transistor T1 and the third transistor T3 and simplify the connection between the second voltage line 052 and each of the second transistor T2 and the fourth transistor T4.

Referring to FIGS. 8-9, in an optional embodiment of the present disclosure, the electrostatic protection circuits 30 may include the first protection circuit 31 and the second protection circuit 32; the pixel driving circuit 40 may include the pulse width modulation circuit 120 and the pulse amplitude modulation circuit 110; the first signal lines 10 may include the first-type signal line 01 and the second-type signal line 02; the first-type signal line 01 may be electrically connected to the pulse width modulation circuit 120, and the second-type signal line 02 may be electrically connected to the pulse amplitude modulation circuit 110; the end portion of the first-type signal line 01 may be electrically connected to the first protection circuit 31; and the end portion of the second-type signal line 02 may be electrically connected to the second protection circuit 32.

The first voltage line may include the first sub-line 51 and the second sub-line 52; the second voltage line may include the third sub-line 53 and the fourth sub-line 54; the first signal terminal S01 and the second signal terminal S02 of the first protection circuit 31 may be electrically connected to the first sub-line 51 and the third sub-line 53 respectively; the first signal terminal S01 and the second signal terminal S02 of the second protection circuit 32 may be electrically connected to the second sub-line 52 and the fourth sub-line 54 respectively; and along the first direction D1, the first sub-line 51 may be between the electrostatic protection circuit 30 and the second sub-line 52; and the third sub-line 53 may be between the electrostatic protection circuit 30 and the fourth sub-line 54.

Referring to FIGS. 8-9, the solution that the first protection circuit 31 and the second protection circuit 32 may be connected to different signals is described in one embodiment. The voltage lines may be respectively configured for the first protection circuit 31 and the second protection circuit 32. The first voltage line may include the first sub-line 51 and the second sub-line 52 which are insulated from each other, and the second voltage line may include the third sub-line 53 and the fourth sub-line 54 which are insulated from each other. The first signal terminal S01 of the first protection circuit 31 may be connected to the first sub-line 51 to obtain the first high voltage, and the second signal terminal S02 of the first protection circuit 31 may be connected to the third sub-line 53 to obtain the first low voltage. The first signal terminal S01 of the second protection circuit 32 may be connected to the second sub-line 52 to obtain the second high voltage, and the second signal terminal S02 of the second protection circuit 32 may be connected to the fourth sub-line 54 to obtain the second low voltage, where the first high voltage may be different from the second high voltage, and/or the first low voltage may be different from the second low voltage. In one embodiment, the first sub-line 51 and the second sub-line 52 may be on one side of the electrostatic protection circuit 30 along the first direction D1; and the third sub-line 53 and the fourth sub-line 54 may be on another side of the electrostatic protection circuit 30 along the first direction D1. In addition, the first sub-line 51 and the third sub-line 53 may be closer to the electrostatic protection circuit 30. That is, the first sub-line 51 may be on the side of the second sub-line 52 facing toward the electrostatic protection circuit 30, and the third sub-line 53 may be on the side of the fourth sub-line 54 facing toward the electrostatic protection circuit 30. In such way, the first protection circuit 31 may be directly connected to the first sub-line 51 and the third sub-line 53, which may be beneficial for reducing the difficulty of connecting the first protection circuit 31 with the first sub-line 51 and the third sub-line 53. The second protection circuit 32 may be connected to the second sub-line 52 and the fourth sub-line 54 through a line-crossing manner. In one embodiment, the arrangement manner of each transistor in the first protection circuit 31 and the second protection circuit 32 may refer to one embodiment shown in FIG. 18, which may not be described in detail herein.

It should be noted that in some other embodiments of the present disclosure, the positions of the first sub-line 51 and the second sub-line 52 in FIG. 19 may be switched, and the positions of the third sub-line 53 and the fourth sub-line 54 in FIG. 19 may be switched. In such way, the second protection circuit 32 may be directly connected to the second sub-line 52 and the fourth sub-line 54, which may be beneficial for reducing the difficulty of connecting the second protection circuit 32 with the second sub-line 52 and the fourth sub-line 54. The first protection circuit 31 may be connected to the first sub-line 51 and the third sub-line 53 through a line-crossing manner.

Referring to FIGS. 19-20, in an optional embodiment of the present disclosure, the electrostatic protection circuits 30 may include the first protection circuit 31 and the second protection circuit 32; the pixel driving circuit 40 may include the pulse width modulation circuit 120 and the pulse amplitude modulation circuit 110; the first signal lines 10 may include the first-type signal line 01 and the second-type signal line 02; the first-type signal line 01 may be electrically connected to the pulse width modulation circuit 120, and the second-type signal line 02 may be electrically connected to the pulse amplitude modulation circuit 110; the end portion of the first-type signal line 01 may be electrically connected to the first protection circuit 31, and the end portion of the second-type signal line 02 may be electrically connected to the second protection circuit 32; and the first signal terminal S01 of the first protection circuit 31 and the first signal terminal S01 of the second protection circuit 32 may be connected to the first voltage line 051, and the second signal terminal S02 of the first protection circuit 31 and the second signal terminal S02 of the second protection circuit 32 may be connected to the second voltage line 052.

Referring to FIGS. 19-20, the solution that the first protection circuit 31 and the second protection circuit 32 may be connected to same signal is described in one embodiment. That is, the first transistor T1 in the first protection circuit 31 and the third transistor T3 in the second protection circuit 32 may be connected to same first voltage line 051; and the second transistor T2 in the first protection circuit 31 and the fourth transistor T4 in the second protection circuit 32 may be connected to same second voltage line 052. For such configuration, different voltage lines may not need to be disposed for the first protection circuits 31 and the second protection circuits 32 respectively; and the first protection circuits 31 and the second protection circuits 32 may share a set of voltage lines, which may be beneficial for reducing the number of voltage lines corresponding to the electrostatic protection circuit 30 and simplifying the wiring complexity. It should be noted that the arrangement manner of the transistors in the first protection circuits 31 and the second protection circuits 32 and the arrangement manner of the first voltage lines 051 and the second voltage lines 052 may refer to above-mentioned embodiments, which may not be described in detail herein.

Referring to FIGS. 2 and 18, in an optional embodiment of the present disclosure, the display region may include the light-emitting element LD and the pixel driving circuit 40 connected to the light-emitting element LD; and the electrostatic protection circuit 30 may not be overlapped with the pixel driving circuit 40 along the direction perpendicular to the plane where the display panel is located.

When the electrostatic protection circuit 30 is disposed in the display panel provided by the present disclosure, in order to realize the electrical connection between the electrostatic protection circuit 30 and the end portion of the first signal line 10, the electrostatic protection circuit 30 may be disposed on the side of the edge of the display panel in the region where the pixel driving circuit 40 is located along the first direction D1, which may avoid the overlapping of the electrostatic protection circuit 30 and the pixel driving circuit 40 along the direction perpendicular to the plane where the display panel is located, thereby being beneficial for avoiding the problem of signal crosstalk between the electrostatic protection circuit 30 and the pixel driving circuit 40 and improving working reliability of the display panel.

Referring to FIGS. 12-18, in an optional embodiment of the present disclosure, the electrostatic protection circuit 30 may be overlapped with the pixel driving circuit 40 along the first direction D1. That is, when the electrostatic protection circuits 30 is disposed in the display panel, the electrostatic protection circuits 30 may be configured on one side or two sides of the pixel driving circuit 40 along the first direction D1. That is, along the first direction D1, the region where the electrostatic protection circuit 30 is located may be overlapped with the region where the pixel driving circuit 40 is located. The pixel driving circuit 40 may be electrically connected to the first signal line 10 extending along the first direction D1, and the electrostatic protection circuit 30 may be electrically connected to the end portion of the first signal line 10. Therefore, the manner of configuring the electrostatic protection circuit 30 to be overlapped with the pixel driving circuit 40 along the first direction D1 may be beneficial for simplifying the wiring of connecting the first signal line 10 with the electrostatic protection circuit 30, thereby being beneficial for simplifying overall wiring complexity of the display panel.

Referring to FIGS. 12-18, in an optional embodiment of the present disclosure, the electrostatic protection circuits 30 may include the first protection circuit 31 and the second protection circuit 32; the pixel driving circuit 40 may include the pulse width modulation circuit 120 and the pulse amplitude modulation circuit 110; the first protection circuit 31 may be connected to the first signal line 10 corresponding to the pulse width modulation circuit 120, and the second protection circuit 32 may be connected to the first signal line 10 corresponding to the pulse amplitude modulation circuit 110; and along the first direction D1, the first protection circuit 31 may be overlapped with the pulse width modulation circuit, and the second protection circuit 32 may be overlapped with the pulse amplitude modulation circuit.

When the electrostatic protection circuits 30 are disposed in the display panel, the electrostatic protection circuits 30 may be divided into the first protection circuit 31 connected to the first signal line 10 corresponding to the pulse width modulation circuit 120, and the second protection circuit 32 connected to the first signal line 10 corresponding to the pulse amplitude modulation circuit 110. Optionally, in the pixel driving circuit 40, the pulse width modulation circuit 120 and the pulse amplitude modulation circuit 110 may be arranged along the second direction D2. Taking FIGS. 17-18 as an example, the pulse width modulation circuit 120 may be above the pulse amplitude modulation circuit 110, such that the first-type signal line 01 connected to the pulse width modulation circuit 120 may also be above the second-type signal line 02 connected to the pulse amplitude modulation circuit 110. In one embodiment, along the first direction D1, the first protection circuit 31 may be configured to be overlapped with the pulse width modulation circuit 120, and the second protection circuit 32 may be configured to be overlapped with the pulse amplitude modulation circuit 110. Therefore, when the first protection circuit 31 is electrically connected to the first-type signal line 01, the first-type signal line 01 may be electrically connected to the first protection circuit 31 without complicated wiring or line-crossing; and similarly, when the second protection circuit 32 is electrically connected to the second-type signal line 02, the second-type signal line 02 may be electrically connected to the second protection circuit 32 without complicated wiring or ling-crossing, thereby being beneficial for simplifying the connection between the first signal line 10 and the electrostatic protection circuit 30 and overall wiring difficulty of the display panel.

Referring to FIGS. 2 and 18, in an optional embodiment of the present disclosure, the display panel may include a planarization layer JY1 and a power wiring layer MO located on the side of the planarization layer JY1 facing toward the light-emitting surface of the display panel; the power lines VEE in the power wiring layer MO may include a plurality of first openings K1; and the first openings K1 may be overlapped with the electrostatic protection circuits 30 along the direction perpendicular to the plane where the light-emitting surface of the display panel is located.

The planarization layer JY1 in the display panel may be made of an organic insulating material. After the organic material undergoes a high-temperature process, some water vapor and other substances may be volatilized. If a large piece of metal is covered on the organic insulating material, the volatile substances of the organic insulating material may be unable to penetrate the dense metal layer, for example, the power wiring layer MO, which may cause the surface of the power wiring VEE in certain regions to form defected protrusion. Therefore, in the present disclosure, the plurality of first openings K1 may be formed on the power lines VEE in the power wiring layer MO. When organic insulating material generates volatile substances, the volatile substances may volatilize through the first openings K1, thereby avoiding the problem of protrusion of the power lines VEE caused by the difficulty of volatilizing the volatile substances. In one embodiment, the first opening K1 on the power line may be overlapped with the electrostatic protection circuit 30 along the direction perpendicular to the plane where the light-emitting surface of the display panel is located, thereby being beneficial for reducing the crosstalk between the electrostatic protection circuit 30 and the power signal on the power line and further improving working reliability of the electrostatic protection circuit 30 in the display panel and the signal stability on the power line.

Referring to FIGS. 2, 8, and 17-19, in an optional embodiment of the present disclosure, the display region may include the light-emitting element LD and the pixel driving circuit 40 connected to the light-emitting element LD; the pixel driving circuit 40 may include the pulse width modulation circuit 120 and the pulse amplitude modulation circuit 110; the first signal lines 10 may include the first-type signal line 01 and the second-type signal line 02; the first-type signal line 01 may be electrically connected to the pulse width modulation circuit 120, and the second-type signal line 02 may be electrically connected to the pulse amplitude modulation circuit 110; the electrostatic protection circuits 30 may include the first protection circuit 31 and the second protection circuit 32; the end portion of the first-type signal line 01 may be electrically connected to the first protection circuit 31, and the end portion of the second-type signal line 02 may be electrically connected to the second protection circuit 32; the protection circuits may include the first circuit group Z1 and the second circuit group Z2; the first circuit group Z1 may include the plurality of first protection circuits 31, and the second circuit group Z2 may include the plurality of second protection circuits 32; the display panel may include the anode soldering pad P01 and the cathode soldering pad P02 connected to the light-emitting element LD; and the anode soldering pad P01 may be overlapped with the second protection circuits 32 in the second circuit group Z2, and may be overlapped with a part of the first protection circuits 31 in the first circuit group Z1.

In the present disclosure, in the region where the electrostatic protection circuits 30 are disposed, the first circuit groups Z1 and the second circuit groups Z2 may be alternately arranged along the second direction D2; the first protection circuit 31 in the first circuit group Z1 may be configured to be electrically connected to the first-type signal line 01 corresponding to the pulse width modulation circuit 120; and the second protection circuit 32 in the second circuit group Z2 may be configured to be electrically connected to the second-type signal line 02 corresponding to the pulse amplitude modulation circuit 110, thereby realizing the conduction of static electricity. In order to make full use of the space of the display panel, the light-emitting element LD may also be configured in the region where the electrostatic protection circuit 30 is disposed. For example, the anode soldering pad P01 and the cathode soldering pad P02 electrically connected to the light-emitting element LD may be configured to be above the transistors corresponding to the first protection circuit 31 and the second protection circuit 32, that is, may be configured at the film layer above the electrostatic protection circuit 30, such that the electrostatic protection circuit 30 and the light-emitting element LD may not interfere with each other in the configuration space. At this point, along the direction perpendicular to the plane where the light-emitting surface of the display panel is located, the anode soldering pad P01 of the light-emitting element LD may be overlapped with the second protection circuits 32 in the second circuit group Z2 and overlapped with a part of the first protection circuits 31 in the first circuit group Z1. In one embodiment, along the first direction D1, the first circuit group Z1 may be located above the second circuit group Z2, which may be equivalent to configuring the light-emitting element LD in the middle region and the lower region of the region where the electrostatic protection circuit 30 is located, thereby realizing reasonable space use of the display panel.

It should be noted that, in order to simplify the film layer configuration on the display panel, the anode soldering pad P01, the cathode soldering pad P02 and the (negative) power line VEE in the display panel may be configured in same film layer. To avoid short circuit, a spacing may be formed by a digging hole manner. For example, a spacing for insulation may be formed between the anode soldering pad P01 and the cathode soldering pad P02, and a spacing for insulation may be formed between the cathode soldering pad P02 and the power line.

Referring to FIGS. 2 and 18, in an optional embodiment of the present disclosure, opening may be formed at both the cathode soldering pad P02 and the anode soldering pad P01; and the opening of the anode soldering pad P01 may be overlapped with the electrostatic protection circuit 30 along the direction perpendicular to the plane where the light-emitting surface of the display panel is located.

When the anode soldering pad P01 and the cathode soldering pad P02 are configured above the planarization layer JY1 in the display panel, openings may be formed on the anode soldering pad P01 and the cathode soldering pad P02. When the organic material in the planarization layer JY1 produces volatile substances, the volatile substances may volatilize through above-mentioned openings, thereby avoiding the protrusion problem of the anode soldering pad P01 and the cathode soldering pad P02 due to the difficulty of volatilization of the volatile substances. In addition, in one embodiment, the opening of the anode soldering pad P01 may be overlapped with the electrostatic protection circuit 30, which may be beneficial for reducing the interference of the electrostatic protection circuit 30 on the signal of the anode soldering pad P01, and improving the light-emitting stability and accuracy of the light-emitting element LD.

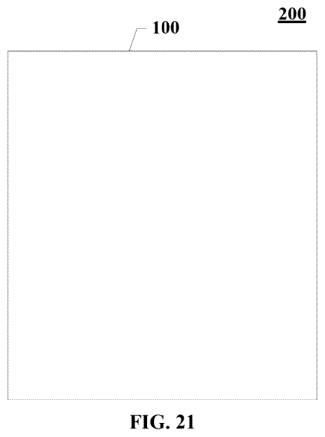

Based on same inventive concept, the present disclosure further provides a display apparatus. FIG. 21 illustrates a structural schematic of the display apparatus according to various embodiments of the present disclosure. Referring to FIG. 21, a display apparatus 200 may include the display panel in any of above-mentioned embodiments. The display apparatus 200 provided in embodiments of the present disclosure may be any electronic device with a display function, such as a touch screen, a mobile phone, a tablet computer, a laptop computer, an e-book, a television or the like. The display apparatus 200 provided in embodiments of the present disclosure may have beneficial effects of the display panel provided in embodiments of the present disclosure, which may refer to the description of the display panel in above-mentioned embodiments and may not be described in detail herein.

It may be understood that the display apparatus 200 of the rectangular structure is taken as an example for illustration in FIG. 21. In some other embodiments of the present disclosure, the display apparatus 200 may also be circular, elliptical or any other feasible shape, which may not be limited in the present disclosure.

It may be seen from above-mentioned embodiments that the present disclosure may at least achieve following beneficial effects.

In the display panel provided by the present disclosure, the shift register circuit may be configured in the display region, and the control signal may be provided to the first signal line through the shift register circuit in the display region; the electrostatic protection circuit may be also configured in the display region; and the shift register circuit and the electrostatic protection circuit may not occupy the non-display region space of the display panel. In such way, the non-display region may not be configured in the display panel, or only the non-display region with a relatively small width may be configured in the display panel, which may be beneficial for realizing borderless or extremely narrow border design of the display panel. When the display panels with borderless structure are spliced to form a large-sized display panel, it may be beneficial for weakening the splicing seam and more beneficial for improving the display effect of the large-sized display panel. When the shift register circuit is configured in the display region, in order to simplify the connection between the shift register and the first signal line and reduce wiring, the connection point between the first signal line and the shift register circuit may be in the non-end region of the first signal line. At this point, the end portions of the first signal line located at two ends along the first direction may float. If static electricity is in subsequent formation process or usage process of the display panel, static electricity may be able to act on the pixel driving circuit through the end portion of the first signal line, which may affect the display effect of the display panel and even possibly damage relevant circuit structure. Therefore, in the present disclosure, the electrostatic protection circuit may be configured in the display region, and the end portion of the first signal line may be electrically connected to the electrostatic protection circuit. When the display panel is subjected to static electricity, the static electricity may be discharged through the static electricity protection circuit which may avoid affecting the display effect of the display panel and the circuit in the display panel, thereby being beneficial for improving overall anti-static ability of the display panel.

It should be noted that in the present disclosure, relational terms such as “first” and “second” may be only configured to distinguish one entity or operation from another entity or operation and may not necessarily require or imply that such actual relationship or order is between these entities or operations. Furthermore, the term “comprise”, “include” or any other variation thereof may be intended to cover a non-exclusive inclusion. Therefore, a process, a method, an article or apparatus including a set of elements may include not only those elements, but also other elements not expressly listed, or also include elements inherent in the process, the method, the article or apparatus. Without further limitations, an element defined by the statement “include . . . ” may not exclude the presence of additional identical elements in the process, the method, the article, or apparatus including such element.

The above may be merely embodiments of the present disclosure, which may make those skilled in the art to understand or implement the present disclosure. Various modifications to embodiments of the present disclosure may be apparent to those skilled in the art. General principles defined in the present disclosure may be implemented in other embodiments without departing from the spirit or scope of the present disclosure. Therefore, the present disclosure may not be limited to embodiments described in the present disclosure but may be accorded the widest scope consistent with the principles and novel features of the present disclosure.

What is claimed is:

1. A display panel, comprising:
a plurality of shift register circuits in a display region and a plurality of first signal lines connected to the plurality of shift register circuits, wherein the plurality of first signal lines extends along a first direction and is arranged along a second direction, and the first direction intersects the second direction; and
a plurality of electrostatic protection circuits disposed in the display region, wherein along the first direction, an electrostatic protection circuit is on a side of an end portion of a first signal line facing toward an edge of the display panel, and the end portion of the first signal line is electrically connected to the electrostatic protection circuit.

2. The display panel according to claim 1, wherein:
the plurality of electrostatic protection circuits includes a first protection circuit and a second protection circuit; and the first protection circuit and the second protection circuit are connected to different signals.

3. The display panel according to claim 2, wherein:
the first protection circuit and the second protection circuit each include a first signal terminal and a second signal terminal; and
the first signal terminal of the first protection circuit is configured to receive a first high voltage, and the second signal terminal of the first protection circuit is configured to receive a first low voltage; and the first signal terminal of the second protection circuit is configured to receive a second high voltage, and the second signal terminal of the second protection circuit is configured to receive a second low voltage, wherein the first high voltage is not equal to the second high voltage, and/or the first low voltage is not equal to the second low voltage.

4. The display panel according to claim 3, wherein:
a voltage value of the first high voltage is V11, a voltage value of the first low voltage is V01, a voltage value of the second high voltage is V12, and a voltage value of the second low voltage is V02, wherein V11−V01=V12−V02; or
a voltage value of the first high voltage is V11, a voltage value of the first low voltage is V01, a voltage value of the second high voltage is V12, and a voltage value of the second low voltage is V02, wherein V11−V01/V12−V02; or
a voltage value of the first high voltage is V11, a voltage value of the first low voltage is V01, a voltage value of the second high voltage is V12, and a voltage value of the second low voltage is V02, wherein V11>V12>0, and V02<V01<0.

5. The display panel according to claim 2, wherein:
a light-emitting element and a pixel driving circuit connected to the light-emitting element are disposed in the display region; the pixel driving circuit includes a pulse width modulation circuit and a pulse amplitude modulation circuit; the plurality of first signal lines includes a plurality of first-type signal lines and a plurality of second-type signal lines; a first-type signal line is electrically connected to the pulse width modulation circuit, and a second-type signal line is electrically connected to the pulse amplitude modulation circuit; and an end portion of the first-type signal line is electrically connected to the first protection circuit, and an end portion of the second-type signal line is electrically connected to the second protection circuit.

6. The display panel according to claim 5, wherein:
the first protection circuit includes a first transistor and a second transistor; a gate electrode and a first electrode of the first transistor are electrically connected to the end portion of the first-type signal line, and a second electrode of the first transistor receives a first high voltage; and a gate electrode and a first electrode of the second transistor receive a first low voltage, and a second electrode of the second transistor is electrically connected to the end portion of the first-type signal line; and
the second protection circuit includes a third transistor and a fourth transistor; a gate electrode and a first electrode of the third transistor are electrically connected to the end portion of the second-type signal line, and a second electrode of the third transistor receives a second high voltage; and a gate electrode and a first electrode of the fourth transistor receive a second low voltage, and the second electrode of the fourth transistor is electrically connected to the end portion of the second-type signal line.

7. The display panel according to claim 6, wherein:
the pixel driving circuit includes a first scan line, a first light-emitting control signal line, a first reset signal line and a frequency sweeping signal line which are electrically connected to the pulse width modulation circuit, and includes a second scan line, a second light-emitting control signal line and a second reset signal line which are electrically connected to the pulse amplitude modulation circuit; and
the first-type signal line includes at least one of the first scan line, the first light-emitting control signal line, the first reset signal line and the frequency-sweeping signal line; and the second-type signal line includes at least one of the second scan line, the second light-emitting control signal line, and the second reset signal line.

8. The display panel according to claim 7, wherein:
the first protection circuit includes a first sub-circuit and a second sub-circuit; the first sub-circuit is connected to the first reset signal line; and the second sub-circuit is connected to at least one of the first scan line, the first light-emitting control signal line and the frequency-sweeping signal line; and
in the first sub-circuit, a channel width of the first transistor is W11, and a channel width of the second transistor is W12; and in the second sub-circuit, a channel width of the first transistor is W21, and a channel width of the second transistor is W22, wherein W11<W21, and/or W12<W22.

9. The display panel according to claim 7, wherein:
the second protection circuit includes a third sub-circuit and a fourth sub-circuit; the third sub-circuit is connected to the second reset signal line; and the fourth sub-circuit is connected to at least one of the second scan line and the second light-emitting control signal line; and
in the third sub-circuit, a channel width of the third transistor is W13, and a channel width of the fourth transistor is W14; and in the fourth sub-circuit, a channel width of the third transistor is W23, and a channel width of the fourth transistor is W24, wherein W13<W23, and/or W14<W24.

10. The display panel according to claim 7, wherein:
the first protection circuit includes a first sub-circuit and a second sub-circuit; the first sub-circuit is connected to the first reset signal line, and the second sub-circuit is connected to at least one of the first scan line, the first light-emitting control signal line, and the frequency sweeping signal line; the second protection circuit includes a third sub-circuit and a fourth sub-circuit; the third sub-circuit is connected to the second reset signal line, and the fourth sub-circuit is connected to at least one of the second scan line and the second light-emitting control signal line; and a channel width of a transistor in the first sub-circuit is same as a channel width of a transistor in the third sub-circuit.

11. The display panel according to claim 1, wherein:
along the first direction, electrostatic protection circuits are disposed on a first side and a second side of the first signal line, wherein the first side and the second side are configured to be opposite to each other.

12. The display panel according to claim 1, wherein:
two opposite end portions of the first signal line along the first direction are electrically connected to electrostatic protection circuits; and
the plurality of electrostatic protection circuits includes a first circuit group and a second circuit group; the first circuit group includes a plurality of first protection circuits, and the second circuit group includes a plurality of second protection circuits; the plurality of the first protection circuits is arranged along the second direction, and the plurality of the second protection circuits is arranged along the second direction; and on a same side of the plurality of first signal lines along the first direction, the first circuit groups and the second circuit groups are arranged alternately; and along the second direction, a distance between two adjacent first protection circuits in the first circuit group is S1, a distance between two adjacent second protection circuits in the second circuit group is S2, and a distance between the first circuit group and the second circuit group which are adjacent to each other is S0, wherein S0>S1, and/or S0>S2; or S1=S2.

13. The display panel according to claim 1, further including:
a pixel driving circuit, wherein:
along the first direction, the pixel driving circuit is on a side of the electrostatic protection circuit away from an edge of the display panel; and
a first voltage line and a second voltage line are disposed at the display region; a first signal terminal of the electrostatic protection circuit is electrically connected to the first voltage line, and a second signal terminal of the electrostatic protection circuit is electrically connected to the second voltage line; and along the first direction, the first voltage line and the second voltage line are on two sides of the electrostatic protection circuit, and the first voltage line is between the electrostatic protection circuit and the pixel driving circuit.

14. The display panel according to claim 13, wherein:
the plurality of electrostatic protection circuits includes a first protection circuit and a second protection circuit; the pixel driving circuit includes a pulse width modulation circuit and a pulse amplitude modulation circuit; the plurality of first signal lines includes a plurality of first-type signal lines and a plurality of second-type signal lines; a first-type signal line is electrically connected to the pulse width modulation circuit, and a second-type signal line is electrically connected to the pulse amplitude modulation circuit; and an end portion of the first-type signal line is electrically connected to the first protection circuit, and an end portion of the second-type signal line is electrically connected to the second protection circuit;
the first voltage line includes a first sub-line and a second sub-line; the second voltage line includes a third sub-line and a fourth sub-line; a first signal terminal and a second signal terminal of the first protection circuit are electrically connected to the first sub-line and the third sub-line, respectively; and a first signal terminal and a second signal terminal of the second protection circuit are electrically connected to the second sub-line and the fourth sub-line, respectively; and
along the first direction, the first sub-line is between the electrostatic protection circuit and the second sub-line, and the third sub-line is between the electrostatic protection circuit and the fourth sub-line.

15. The display panel according to claim 13, wherein:
the plurality of electrostatic protection circuits includes a first protection circuit and a second protection circuit; the pixel driving circuit includes a pulse width modulation circuit and a pulse amplitude modulation circuit; the plurality of first signal lines includes a plurality of first-type signal lines and a plurality of second-type signal lines; a first-type signal line is electrically connected to the pulse width modulation circuit, and a second-type signal line is electrically connected to the pulse amplitude modulation circuit; and an end portion of the first-type signal line is electrically connected to the first protection circuit, and an end portion of the second-type signal line is electrically connected to the second protection circuit; and
a first signal terminal of the first protection circuit and a first signal terminal of the second protection circuit are connected to the first voltage line; and a second signal terminal of the first protection circuit and a second signal terminal of the second protection circuit are connected to the second voltage line.

16. The display panel according to claim 1, wherein:
a light-emitting element and a pixel driving circuit connected to the light-emitting element are disposed in the display region; and the electrostatic protection circuit is not overlapped with the pixel driving circuit along a direction perpendicular to a plane of the display panel; or
along the first direction, the electrostatic protection circuit is overlapped with the pixel driving circuit; or
the electrostatic protection circuit is overlapped with the light-emitting element along a direction perpendicular to a plane of a light-emitting surface of the display panel.

17. The display panel according to claim 16, wherein:
the plurality of electrostatic protection circuits includes a first protection circuit and a second protection circuit; the pixel driving circuit includes a pulse width modulation circuit and a pulse amplitude modulation circuit; and the first protection circuit is connected to the first signal line corresponding to the pulse width modulation circuit, and the second protection circuit is connected to the first signal line corresponding to the pulse amplitude modulation circuit; and
along the first direction, the first protection circuit is overlapped with the pulse width modulation circuit, and the second protection circuit is overlapped with the pulse amplitude modulation circuit.

18. The display panel according to claim 1, wherein:
a light-emitting element and a pixel driving circuit connected to the light-emitting element are disposed in the display region; the pixel driving circuit includes a pulse width modulation circuit and a pulse amplitude modulation circuit; the plurality of first signal lines includes a plurality of first-type signal lines and a plurality of second-type signal lines; a first-type signal line is electrically connected to the pulse width modulation circuit, and a second-type signal line is electrically connected to the pulse amplitude modulation circuit; the plurality of electrostatic protection circuits includes a first protection circuit and a second protection circuit;
an end portion of the first-type signal line is electrically connected to the first protection circuit, and an end portion of the second-type signal line is electrically connected to the second protection circuit; the plurality of electrostatic protection circuits includes a first circuit group and a second circuit group; and the first circuit group includes a plurality of first protection circuits, and the second circuit group includes a plurality of second protection circuits; and
the display panel includes an anode soldering pad and a cathode soldering pad which are connected to the light-emitting element, and the anode soldering pad is overlapped with second protection circuits in the second circuit group and overlapped with a part of first protection circuits in the first circuit group.

19. The display panel according to claim 18, wherein:
openings are formed at both the anode soldering pad and the cathode soldering pad; and along a direction perpendicular to a plane of a light-emitting surface of the display panel, an opening of the anode pad is overlapped with the electrostatic protection circuit.

20. A display apparatus, comprising:
a display panel, comprising:
a plurality of shift register circuits in a display region and a plurality of first signal lines connected to the plurality of shift register circuits, wherein the plurality of first signal lines extends along a first direction and is arranged along a second direction, and the first direction intersects the second direction; and
a plurality of electrostatic protection circuits disposed in the display region, wherein along the first direction, an electrostatic protection circuit is on a side of an end portion of a first signal line facing toward an edge of the display panel, and the end portion of the first signal line is electrically connected to the electrostatic protection circuit.
